(19) United States
(12) Patent Application Publication
(10) Pub. No.: US 2012/0269489 A1
(43) Pub. Date: Oct. 25, 2012

(54) DRAM PACKAGE, DRAM MODULE INCLUDING DRAM PACKAGE, GRAPHIC MODULE INCLUDING DRAM PACKAGE AND MULTIMEDIA DEVICE INCLUDING DRAM PACKAGE

(76) Inventors: Sungjoo PARK, Anyang-si (KR); InDal SONG, Seoul (KR); Jangseok CHOI, Seoul (KR); Yong-Jin KIM, Suwon-si (KR)

(21) Appl. No.: 13/451,071

(22) Filed: Apr. 19, 2012

(30) Foreign Application Priority Data
Apr. 19, 2011 (KR) 10-2011-0036351

(51) Int. Cl. H01L 23/498; H04N 5/77

(52) U.S. Cl. 386/224; 257/738; 257/E23.069; 386/E05.069

(57) ABSTRACT

A DRAM package includes a DRAM package body, and a ball grid array formed at a lower surface of the DRAM package body. The ball grid array includes a plurality of solder balls arranged in the equal interval along row and column directions. The DRAM package is included in an electronic apparatus.

### CROSS-REFERENCE TO RELATED APPLICATIONS

This application claims the benefit of priority, under 35 U.S.C §119, of Korean Patent Application No. 10-2011-0036351 filed Apr. 19, 2011, the entirety of which is incorporated by reference herein.

### BACKGROUND OF THE INVENTION

1. Field of the Invention

Exemplary embodiments relate to a semiconductor memory, and more particularly, to a DRAM package, a DRAM module including the DRAM package, a graphic module including the DRAM package, and a multimedia device including the DRAM package.

2. Description of the Related Art

A semiconductor memory device may be a memory device which is fabricated using semiconductors such as silicon (Si), germanium (Ge), gallium arsenide (GaAs), indium phosphide (InP), and the like. Semiconductor memory devices may be classified into volatile memory devices and nonvolatile memory devices.

The volatile memory devices may lose stored contents in a power-off state. The volatile memory devices include a static RAM (SRAM), a dynamic RAM (DRAM), a synchronous DRAM (SDRAM), and the like. The nonvolatile memory devices may retain stored contents in the power-off state. The nonvolatile memory devices may include a read only memory (ROM), a programmable ROM (PROM), an electrically programmable ROM (EPROM), an electrically erasable and programmable ROM (EEPROM), a flash memory device, a phase-change RAM (PRAM), a magnetic RAM (MRAM), a resistive RAM (RRAM), a ferroelectric RAM (FRAM), and the like.

### SUMMARY OF THE INVENTION

The present general inventive concept provides a semiconductor package having one or more semiconductor devices, a semiconductor module including the semiconductor package, and an electronic apparatus including the semiconductor package.

Additional aspects and advantages of the present general inventive concept will be set forth in part in the description which follows and, in part, will be obvious from the description, or may be learned by practice of the general inventive concept.

The foregoing and/or other features and utilities of the present general inventive concept may be achieved by providing a DRAM package which may include a DRAM package body and a ball grid array formed at a lower surface of the DRAM package body and having a plurality of solder balls arranged at an equal interval along row and column directions.

The plurality of solder balls may be arranged in an 11-by-7 matrix.

The plurality of solder balls may include 22 solder balls assigned to a power and one solder ball assigned to a reserved for future use.

The power assigned to the 22 solder balls includes a high voltage, a power supply voltage, a ground voltage, an input/output power supply voltage, and an input/output ground voltage.

The 22 solder balls assigned to the power may include 2 solder balls assigned to a high voltage, 6 solder balls assigned to a power supply voltage, 8 solder balls assigned to a ground voltage, 2 solder balls assigned to an input/output power supply voltage, and 4 solder balls assigned to an input/output ground voltage.

The 22 solder balls assigned to the power may include 2 solder balls assigned to a high voltage, 7 solder balls assigned to a power supply voltage, 7 solder balls assigned to a ground voltage, 2 solder balls assigned to an input/output power supply voltage, and 4 solder balls assigned to an input/output ground voltage.

The 22 solder balls assigned to the power may include 2 solder balls assigned to a high voltage, 7 solder balls assigned to a power supply voltage, 8 solder balls assigned to a ground voltage, 2 solder balls assigned to an input/output power supply voltage, and 3 solder balls assigned to an input/output ground voltage.

The plurality of solder balls may include 23 solder balls assigned to a power and exclude a solder ball assigned to a reserved for future use.

The 23 solder balls assigned to the power may include 2 solder balls assigned to a high voltage, 7 solder balls assigned to a power supply voltage, 8 solder balls assigned to a ground voltage, 2 solder balls assigned to an input/output power supply voltage, and 4 solder balls assigned to an input/output ground voltage.

The plurality of solder balls may be disposed within a rectangular region of 5.9 mm by 9.1 mm.

A pitch among the plurality of solder balls may be 0.8 mm.

A solder ball of a first row and a first column among the plurality of solder balls may be assigned to an input/output power supply voltage.

A solder ball of a first row and a seventh column among the plurality of solder balls may be assigned to an input/output power supply voltage.

A solder ball of a twelfth row and a first column among the plurality of solder balls may be assigned to an eighth address.

A solder ball of an eleventh row and a seventh column among the plurality of solder balls may be assigned to a seventh address.

Among the plurality of solder balls, solder balls of the eighth to eleventh rows and the first column, the eighth to eleventh rows and the second column, the eighth to eleventh rows and the sixth column, and the eighth to eleventh rows and the seventh column may be assigned to addresses.

The foregoing and/or other features and utilities of the present general inventive concept may also be achieved by providing a DRAM module which may include a plurality of DRAM packages provided on an upper surface of a printed circuit board, and a connector formed at one side of the printed circuit board and electrically connected with the plurality of DRAM packages, each of the plurality of DRAM packages being connected with the printed circuit board via a ball grid array, and the ball grid array including a plurality of solder balls arranged in the equal interval along a row direction and arranged in the equal interval along a column direction.

The plurality of solder balls may be arranged in an 11-by-7 matrix.

The DRAM module may further include a plurality of buffers disposed between the plurality of DRAM packages and the connector.

The DRAM module may further include a plurality of lower DRAM package formed at a lower surface of the printed circuit board and electrically connected with the connector, and the plurality of lower DRAM packages may have the same structure as the plurality of DRAM packages.

The plurality of DRAM packages and the plurality of lower DRAM packages may be electrically interconnected through a plurality of via holes penetrating the printed circuit board.

The DRAM module may further include a plurality of pads provided at the printed circuit board so as to connected with solder balls of the plurality of DRAM packages, and at least one of the plurality of via holes may be formed at the same location of the plurality of pads.

The DRAM module may be further include a plurality of pads provided at the printed circuit board so as to connected with solder balls of the plurality of DRAM packages, and at least one of the plurality of via holes may be formed between the plurality of pads.

The DRAM module may further include a plurality of buffers provided between the DRAM packages and the connector, and the DRAM packages may be disposed in two lines along a direction parallel with the one side of the printed circuit board.

The foregoing and/or other features and utilities of the present general inventive concept may also be achieved by providing a graphic module which may include a graphic processor unit provided on a printed circuit board, and at least one DRAM package electrically connected with the graphic processor unit and connected with the printed circuit board via a ball grid array which may include a plurality of solder balls arranged in the equal interval along a row direction and arranged at an equal interval along a column direction.

The foregoing and/or other features and utilities of the present general inventive concept may also be achieved by providing a multimedia device which may include a processor, a DRAM package, an audio unit, a modem unit, a storage unit, a graphic unit, an interface unit, and an image processor unit configured to operate according to a control of the processor, a speaker configured to communicate with the audio unit, a user input interface configured to operate according to a control of the interface unit, a camera configured to operate according to a control of the image processor unit, and a monitor configured to operate according to a control of the graphic unit, wherein the DRAM package is connected with a printed circuit board via a ball grid array, and the ball grid array includes a plurality of solder balls arranged in the equal interval along a row direction and arranged in the equal interval along a column direction.

A combination of at least two of the processor, the audio unit, the modem unit, the storage unit, the graphic unit, the interface unit, and the image processor unit may be formed in a system-on-chip.

The printed circuit board, the DRAM package, the processor, the audio unit, the modem unit, the storage unit, the graphic unit, the interface unit, the image processor unit, the speaker, the user input interface, the camera, and the monitor may be formed in a mobile device.

The graphic unit may be a graphic module with at least one DRAM package and the graphic module may communicate with the processor via a connector.

The DRAM package may be a DRAM module with another DRAM package and the DRAM module may communicate with the processor via a connector.

The storage unit may be a storage module to communicate with the processor via a connector.

A DRAM module may be further provided with a plurality of first DRAM packages provided on an upper surface of a printed circuit board, a plurality of second DRAM packages provided on a lower surface of the printed circuit board, and a connector formed at one side of the printed circuit board and electrically connected with the plurality of first and second DRAM packages, wherein each of the plurality of first and second DRAM package is connected with the printed circuit board via a ball grid array, wherein the ball grid array includes a plurality of solder balls arranged in the equal interval along a row direction and arranged in the equal interval along a column direction, and wherein the plurality of first DRAM packages is electrically connected with the plurality of second DRAM packages through a plurality of via holes, which penetrate the printed circuit board, formed at one or more spaces overlapped with spaces where the solder balls are provided.

A DRAM module may be further provided with a plurality of first DRAM packages provided on an upper surface of a printed circuit board, a plurality of second DRAM packages provided on a lower surface of the printed circuit board, and a connector formed at one side of the printed circuit board and electrically connected with the plurality of first and second DRAM packages, wherein each of the plurality of first and second DRAM package is connected with the printed circuit board via a ball grid array, wherein the ball grid array includes a plurality of solder balls arranged in the equal interval along a row direction and arranged in the equal interval along a column direction, and wherein the plurality of first DRAM packages is electrically connected with the plurality of second DRAM packages through a plurality of via holes, which penetrate the printed circuit board, formed at one or more spaces between spaces where the solder balls are provided.

The foregoing and/or other features and utilities of the present general inventive concept may also be achieved by providing an electronic apparatus including a circuit board provided with a function unit configured to perform an operation of the electronic apparatus using data, and formed with pads thereon, and at least one semiconductor package electrically connected with the function unit to store at least one of the data and the processed data, and formed with a ball grid array to be connected to the respective pads of the circuit board, the ball grid array including a plurality of solder balls arranged at an equal interval along a row direction and arranged at the equal interval along a column direction to correspond to the respective pads.

The electronic apparatus may further include a single housing having the circuit board and the semiconductor package.

The electronic apparatus may further include a single housing having the circuit board formed with a connector to be connected to the semiconductor package.

The foregoing and/or other features and utilities of the present general inventive concept may also be achieved by providing a semiconductor package including a semiconductor package body formed with one or more semiconductor chips, and a ball grid array formed at a lower surface of the semiconductor package body, the ball grid array including a plurality of solder balls disposed in an area of the lower surface of the semiconductor package body and arranged at a same interval along row and column directions thereof.

The one or more semiconductor chips may include one or more DRAM packages.

The foregoing and/or other features and utilities of the present general inventive concept may also be achieved by providing an electronic apparatus including a circuit board having a function unit and a pad array having pads, and a semiconductor package having a semiconductor package body formed with one or more semiconductor chips, and a ball grid array formed at a lower surface of the semiconductor package body, the ball grid array including a plurality of solder balls disposed in an area of the lower surface of the semiconductor package body and arranged at a same interval along row and column directions thereof to correspond to the respective pads of the pad array.

The function unit may include at least one of a graphic unit, an image processing unit, an interface unit, an audio unit, a storage unit, and a user interface unit.

The semiconductor package may include a first semiconductor package having a first signal and power assignment of the solder balls of the ball grid array and a second semiconductor package having a second signal and power assignment of the solder balls of the ball grid array. The pads of the pad array of the circuit board may correspond to the solder balls of the ball grid array of the first semiconductor package and the second semiconductor package.

The circuit board comprises one or more via holes formed an area of the pad array between the lower surface and an upper surface to electrically connect conductive material of the lower surface and the upper surface of the circuit board.

The first signal and power assignment of the first semiconductor package and the second signal and power assignment of the second semiconductor package may include a common signal and power assignment.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a diagram illustrating a DRAM package according to an exemplary embodiment of the inventive concept.

FIG. 2 is a diagram illustrating a lower surface of the DRAM package of FIG. 1.

FIG. 3 is a diagram illustrating signals assigned to solder balls of a DRAM package according to an exemplary embodiment of the inventive concept.

FIG. 4 is a diagram illustrating a printed circuit board corresponding to a DRAM package according to an exemplary embodiment of the inventive concept.

FIG. 5 is a diagram illustrating one of a plurality of DRAM regions of the printed circuit board of FIG. 4.

FIGS. 6 to 8 are diagrams illustrating a DRAM module, in which DRAM packages and a printed circuit board are connected, according to an exemplary embodiment of the inventive concept.

FIG. 9 is a diagram illustrating a DRAM package according to another exemplary embodiment of the inventive concept.

FIG. 10 is a diagram illustrating a lower surface of the DRAM package of FIG. 9.

FIG. 11 is a diagram illustrating signals assigned to solder balls of a DRAM package according to an exemplary embodiment of the inventive concept.

FIG. 12 is a diagram illustrating signals assigned to solder balls of a DRAM package according to an exemplary embodiment of the inventive concept.

FIG. 13 is a diagram illustrating signals assigned to solder balls of a DRAM package according to an exemplary embodiment of the inventive concept.

FIG. 14 is a diagram illustrating signals assigned to solder balls of a DRAM package according to an exemplary embodiment of the inventive concept.

FIG. 15 is a diagram illustrating a printed circuit board corresponding to a DRAM package in FIGS. 9 and 10.

FIG. 16 is a diagram illustrating one of a plurality of DRAM regions of the printed circuit board of FIG. 15 according to an exemplary embodiment of the inventive concept.

FIG. 17 is a diagram illustrating one of a plurality of DRAM regions of the printed circuit board of FIG. 15 according to an exemplary embodiment of the inventive concept.

FIG. 18 is a diagram illustrating one of a plurality of DRAM regions of the printed circuit board of FIG. 15 according to an exemplary embodiment of the inventive concept.

FIGS. 19 to 21 are diagrams illustrating a DRAM module, in which DRAM packages and a printed circuit board are connected, according to an exemplary embodiment of the inventive concept.

FIG. 22 is a diagram illustrating a DRAM module, in which DRAM packages and a printed circuit board are connected, according to an exemplary embodiment of the inventive concept.

FIG. 23 is a diagram illustrating a DRAM module, in which DRAM packages and a printed circuit board are connected, according to an exemplary embodiment of the inventive concept.

FIG. 24 is a diagram illustrating a DRAM module, in which DRAM packages and a printed circuit board are connected, according to an exemplary embodiment of the inventive concept.

FIG. 25 is a graphic module according to an exemplary embodiment of the inventive concept.

FIG. 26 is a block diagram a multimedia device 1000 including a DRAM package according to an exemplary embodiment of the inventive concept.

FIG. 27 is a block diagram a multimedia device 1000 including a DRAM package according to an exemplary embodiment of the inventive concept.

FIG. 28 is a block diagram a multimedia device 1000 including DRAM packages according to an exemplary embodiment of the inventive concept.

FIG. 29 is a block diagram a multimedia device 1000 including DRAM packages according to an exemplary embodiment of the inventive concept.

FIG. 30 is a diagram illustrating a smart phone device according to an exemplary embodiment of the inventive concept.

FIG. 31 is a diagram illustrating a tablet computer apparatus according to an exemplary embodiment of the inventive concept.

FIG. 32 is a diagram illustrating a mobile computer apparatus according to an exemplary embodiment of the inventive concept.

FIG. 33 is a diagram illustrating a computer apparatus according to an exemplary embodiment of the inventive concept.

FIG. 34 is a diagram illustrating a television apparatus according to an exemplary embodiment of the inventive concept.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept while referring to the figures. This inventive concept may, however, be embodied in many different forms and should not be construed as limited to the embodiments set forth herein. Rather, these embodiments are provided so that this disclosure will be thorough and complete, and will fully convey the scope of the inventive concept to those skilled in the art. In the drawings, the size and relative sizes of layers and regions may be exaggerated for clarity.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

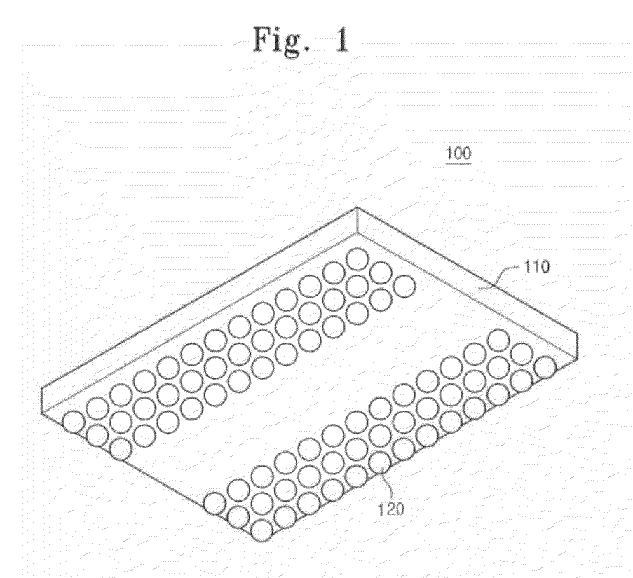

FIG. 1 is a diagram illustrating a semiconductor package according to an exemplary embodiment of the inventive concept. Hereinafter, a DRAM package 100 may be illustrated as an example of the semiconductor package having one or more semiconductor chips or one or more memory devices. Referring to FIG. 1, the DRAM package 100 may include a DRAM package body 110 and a ball grid array (BGA) 120. The ball grid array 120 may be provided at a lower surface of the DRAM package 100. The DRAM package body 110 may include one more semiconductor memory chips formed as a package and electrically connected to the ball grid array 120. The one or more semiconductor memory chips may be one or more DRAMs. The DRAMs may communicate with one or more external devices through the ball grid array 120 to receive or transmit data (or signals) from or to the external devices and/or to store the data (signals) therein. The ball grid array 120 may be formed on a substrate of the DRAM package. It is possible that the ball grid array 120 can be formed on a surface of one of the DRAMs.

The ball grid array 120 may include a plurality of solder balls. The plurality of solder balls may connect the DRAM package body 110 and a printed circuit board (not shown). The plurality of solder balls may be formed of a conductive material.

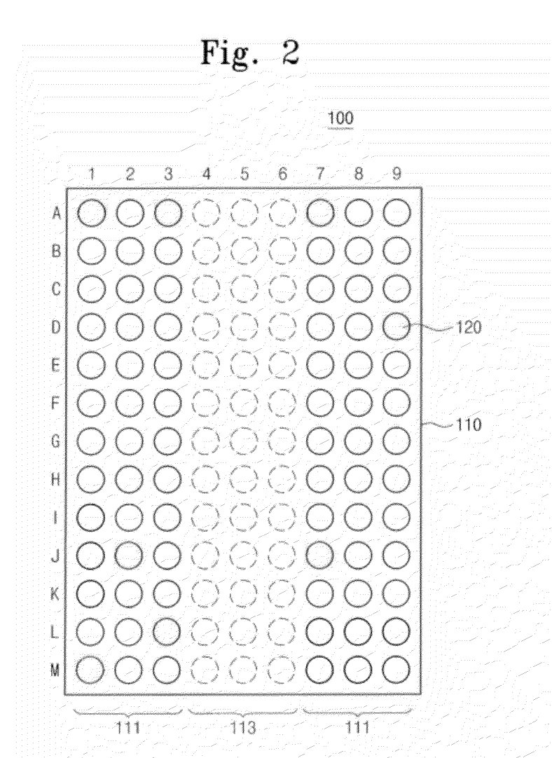

FIG. 2 is a diagram illustrating a lower surface of the DRAM package 100 of FIG. 1. Referring to FIG. 2, solder balls of a ball grid array 120 may be arranged at a lower surface of the DRAM package 100 in a 13-by-9 matrix. 13 rows of the ball grid array 120 may be defined by an A row through an M row, respectively, and 9 columns may be defined by a first column through a ninth column, respectively.

The first to third columns and the seventh to ninth columns of the ball grid array 120 may be disposed in solder ball regions 111. Solder balls may be provided at the solder ball regions 111. The fourth to sixth columns of the ball grid array 120 may be a dummy solder ball region 113. No solder balls may be provided at the dummy solder ball region 113. That is, a total of 78 solder balls may be provided at the ball grid array 120.

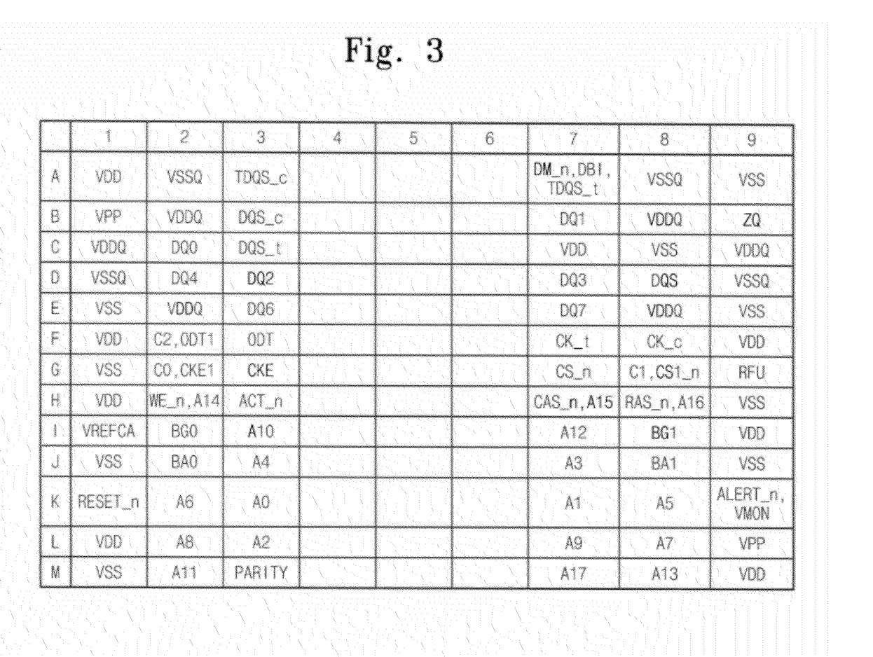

FIG. 3 is a diagram illustrating signals assigned to solder balls of a DRAM package according to an exemplary embodiment of the inventive concept. Referring to FIGS. 1, 2, and 3, solder balls in the A row and the first to third columns may be assigned to a power supply voltage VDD, an input/output ground voltage VSSQ, and a signal TDQS_c, respectively. When a DRAM package 100 is configured to have an ×4 input/output organization, the signal TDQS_c may not be used. No solder balls may be provided at intersections of the A row and the fourth to sixth columns. A solder ball of the A row and the seventh column may be assigned to signals DM_n, DBI, and TDQS_t. When the DRAM package 100 is configured to have the ×4 input/output organization, the signal TDQS_t may not be used. Solder balls of the A row and the eighth and ninth columns may be assigned to an input/output ground voltage VSSQ and a ground voltage VSS, respectively. The ×4 input/output organization may be a bit bank organized with rows and columns by 4 bits, for example.

Solder balls of the B row and the first to third columns may be assigned to a high voltage VPP, an input/output power supply voltage VDDQ, and a signal DQS_c, respectively. No solder balls may be provided at intersections of the B row and the fourth to sixth columns. Solder balls of the B row and the seventh to ninth columns may be assigned to the first data signal DQ1, an input/output power supply voltage VDDQ, and a signal ZQ respectively.

Solder balls of the C row and the first to third columns may be assigned to an input/output power supply voltage VDDQ, data signal DQ0, and a signal DQS_t, respectively. No solder balls may be provided at intersections of the C row and the fourth to sixth columns. Solder balls of the C row and the seventh to ninth columns may be assigned to a power supply voltage VDD, a ground voltage VSS, and an input/output power supply voltage VDDQ, respectively.

Solder balls of the D row and the first to third columns may be assigned to an input/output ground voltage VSSQ, a data signal DQ4, and a data signal DQ2, respectively. When the DRAM package 100 is configured to have the ×8 input/output organization, the data signal DQ4 may not be used. No solder balls may be provided at intersections of the D row and the fourth to sixth columns. Solder balls of the D row and the seventh to ninth columns may be assigned to a data signal DQ3, a signal DQS, and an input/output ground voltage VSSQ, respectively. When the DRAM package 100 is configured to have an ×8 input/output organization, the signal DQS may not be used. The ×8 input/output organization may be a bit bank organized with rows and columns by 8 bits

Solder balls of the E row and the first to third columns may be assigned to a ground voltage VSS, an input/output power supply voltage VDDQ, and a data signal DQ6, respectively. When the DRAM package 100 is configured to have the ×8 input/output organization, the data signal DQ6 may not be used. No solder balls may be provided at intersections of the E row and the fourth to sixth columns. Solder balls of the E row and the seventh to ninth columns may be assigned to a data signal DQ7, an input/output power supply voltage VDDQ, and a ground voltage VSS, respectively. When the DRAM package 100 is configured to have the ×8 input/output organization, the data signal DQ7 may not be used.

A solder ball of the F row and the first column may be assigned to a power supply voltage VDD, and a solder ball of the F row and the second column may be assigned to signals C2 and ODT1. A solder ball of the F row and the third column may be assigned to a signal ODT. No solder balls may be provided at intersections of the F row and the fourth to sixth columns. Solder balls of the F row and the seventh to ninth columns may be assigned to a signal CK_t, a signal CK_c, and a power supply voltage VDD, respectively.

A solder ball of the G row and the first column may be assigned to a ground voltage VSS, and a solder ball of the G row and the second column may be assigned to signals C0 and CKE1. A solder ball of the G row and the third column may be assigned to a signal CKE. No solder balls may be provided at intersections of the G row and the fourth to sixth columns. A solder ball of the G row and the seventh column may be assigned to a signal CS_n. A solder ball of the G row and the eighth column may be assigned to signals C1 and CS1_n. A solder ball of the G row and the ninth column may be assigned to a reserved for future use (RFU).

A solder ball of the H row and the first column may be assigned to a power supply voltage VDD, and a solder ball of the H row and the second column may be assigned to a signal WE_n and an address signal A14. A solder ball of the H row and the third column may be assigned to a signal ACT_n. No solder balls may be provided at intersections of the H row and the fourth to sixth columns. A solder ball of the H row and the seventh column may be assigned to a signal CAS_n and an address signal A15. A solder ball of the H row and the eighth column may be assigned to a signal RAS_n and an address signal A16. A solder ball of the H row and the ninth column may be assigned to a ground voltage VSS.

Solder balls of the I row and the first to third columns may be assigned to a signal VREFCA, a block group address signal BG0, and an address signal A10, respectively. No solder balls may be provided at intersections of the I row and the fourth to sixth columns. Solder balls of the I row and the seventh to ninth columns may be assigned to an address signal A12, a block group address signal BG1, and a power supply voltage VDD, respectively.

Solder balls of the J row and the first to third columns may be assigned to a ground voltage VSS, a block address signal BA0, and an address signal A4, respectively. No solder balls may be provided at intersections of the J row and the fourth to sixth columns. Solder balls of the J row and the seventh to ninth columns may be assigned to an address signal A3, a block address signal BA1, and a ground voltage VSS, respectively.

Solder balls of the K row and the first to third columns may be assigned to a signal RESET_n, an address signal A6, and an address signal A0, respectively. No solder balls may be provided at intersections of the K row and the fourth to sixth columns. Solder balls of the K row and the seventh and eighth columns may be assigned to address signals A1 and A5, respectively. A solder ball of the K row and the ninth column may be assigned to a signal ALERT_n and/or a signal VMON, which may be used to monitor a voltage used therein.

Solder balls of the L row and the first to third columns may be assigned to a power supply voltage VDD, an address signal A8, and an address signal A2, respectively. No solder balls may be provided at intersections of the L row and the fourth to sixth columns. Solder balls of the L row and the seventh to ninth columns may be assigned to an address signal A9, an address signal A7, and a high voltage VPP, respectively.

Solder balls of the M row and the first to third columns may be assigned to a ground voltage VSS, an address signal A11, and a signal PARITY, respectively. No solder balls may be provided at intersections of the M row and the fourth to sixth columns. Solder balls of the M row and the seventh to ninth columns may be assigned to an address signal A17, an address signal A13, and a power supply voltage VDD, respectively.

In the DRAM package, 29 solder balls may be assigned to a power, and one solder ball may be assigned to a reserved for future use (RFU). The 29 solder balls assigned to the power may be 9 solder balls assigned to a ground voltage VSS, 8 solder balls assigned to a power supply voltage VDD, 4 solder balls assigned to an input/output ground voltage VSSQ, 6 solder balls assigned to an input/output power supply voltage VDDQ, and 2 solder balls assigned to a high voltage VPP.

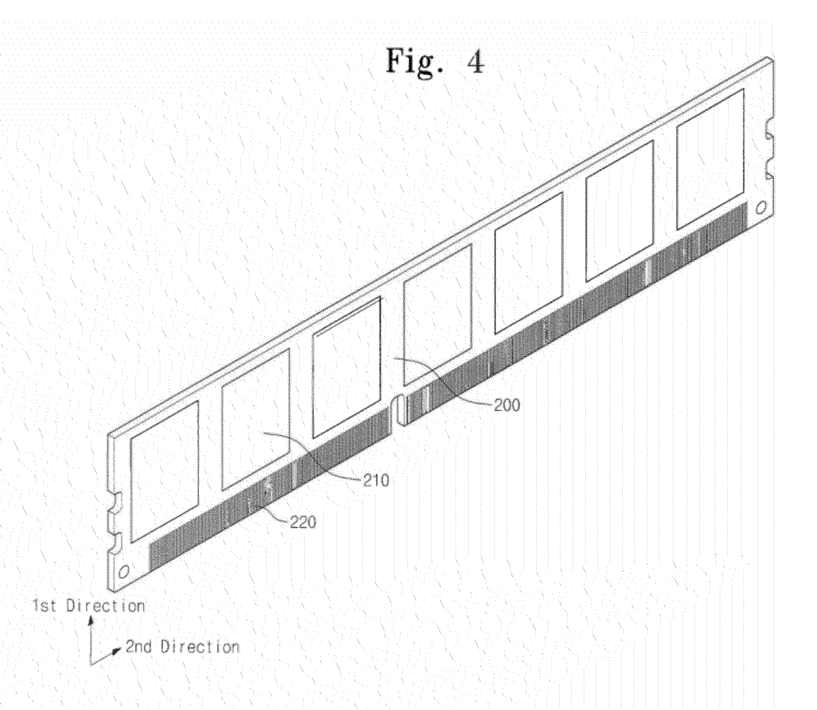

FIG. 4 is a diagram illustrating a printed circuit board 200 corresponding to one or more DRAM packages according to an exemplary embodiment of the inventive concept. Referring to FIG. 4, the printed circuit board 200 may include a plurality of DRAM regions 210 and a connector 220.

DRAM packages 100 according to an exemplary embodiment of the inventive concept may be connected with the plurality of DRAM regions 210, respectively. That is, a plurality of DRAM packages 100 may be connected with the printed circuit board 200. The DRAM packages 100 can be provided at upper and lower surfaces of the printed circuit board 200. For example, DRAM packages 100 may be provided at upper and lower surfaces of each of the plurality of DRAM regions 210, respectively.

Each of the plurality of DRAM regions 210 may be connected with the connector 220 via conductive lines (not illustrated). The connector 220 can include a plurality of conductive plates. The connector 220 may be connected with a slot of an external host. That is, the conductive plates of the connector 220 may be connected to corresponding terminals of the slot of the external host to transmit and receive the power, signals, and data therebetween.

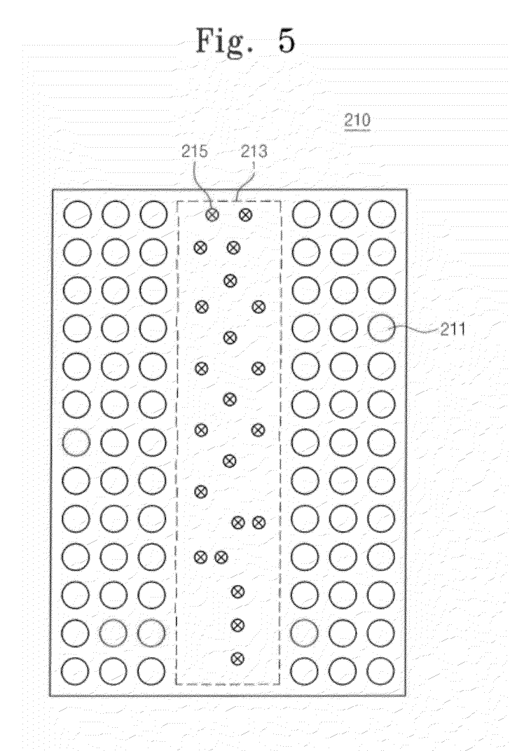

FIG. 5 is a diagram illustrating one of a plurality of DRAM regions 210 of FIG. 4. Referring to FIG. 5, each DRAM region 210 may include pads 211 and a routing region 213. The pads 211 may be formed at the same locations of solder balls of a ball grid array 120 of a DRAM package 100. The routing region 213 may be formed at the same location as a dummy solder ball region 113 of each DRAM package 100.

A plurality of via holes 215 may be formed at the routing region 213. The plurality of via holes 215 may penetrate a body of the printed circuit board 200 to electrically connect an upper surface and a lower surface of the printed circuit board 200. Wires may be formed at the DRAM region 210 to electrically connect the pads 211 and the plurality of via holes 215. Conductive materials may be disposed in the via holes 215 such that the DRAM packages can be electrically connected to the pads 211 of the DRAM regions 210 of the printed circuit board 200 and/or to the connector 220 of the printed circuit board 200.

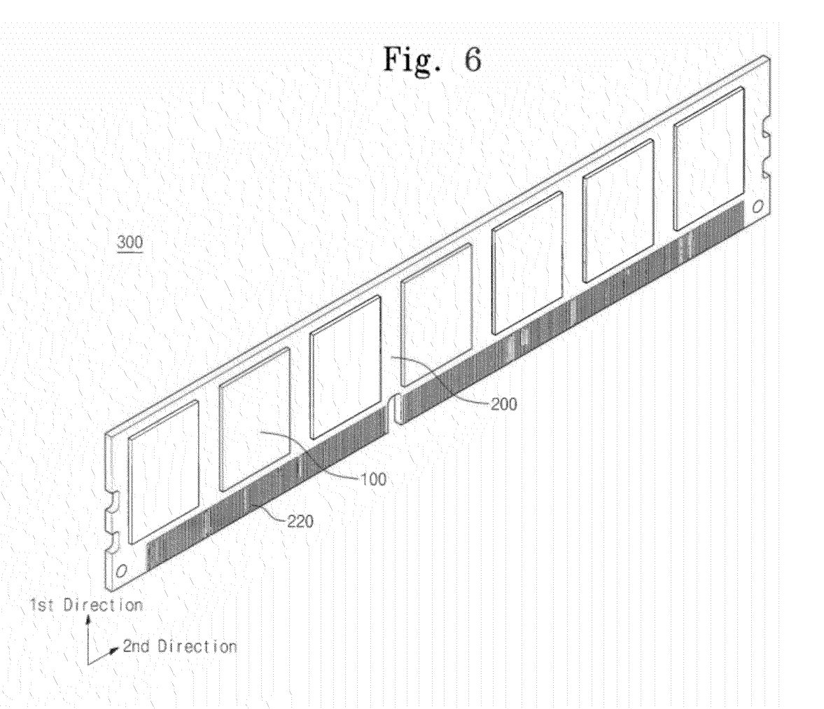

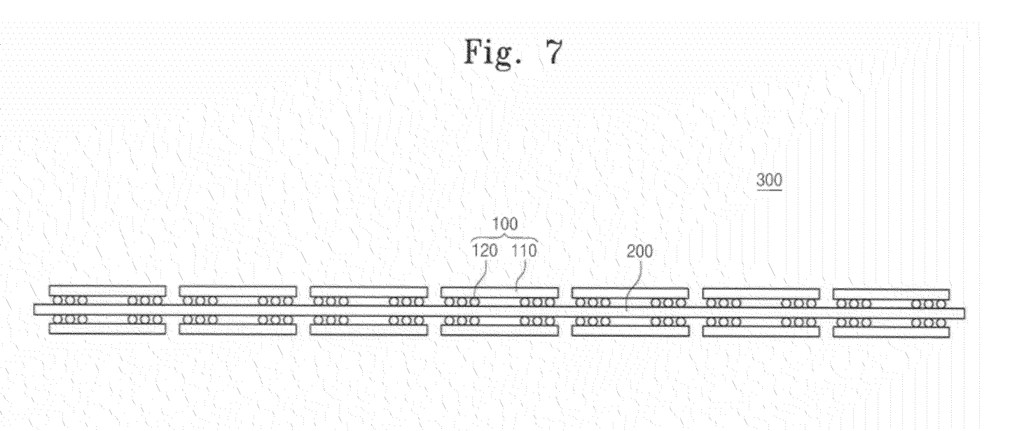

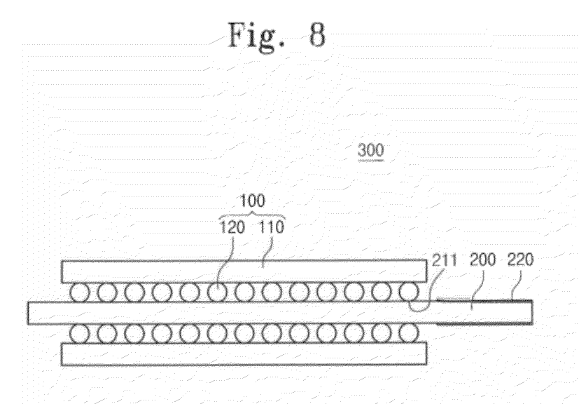

FIGS. 6, 7, and 8 are diagrams illustrating a DRAM module, in which DRAM packages and a printed circuit board are connected, according to an exemplary embodiment of the inventive concept. Exemplarily, a cross-section view of a DRAM module 300 is illustrated in FIG. 6, a view of the DRAM module 300 in a first direction is illustrated in FIG. 7, and a view of the DRAM module 300 in a second direction is illustrated in FIG. 8.

A plurality of DRAM packages 100 may be connected at upper and lower surfaces of the printed circuit board 200, respectively. Each DRAM package 100 may include a DRAM package body 110 and a ball grid array 120. A plurality of solder balls of the ball grid array 120 may be connected with pads 211 of the printed circuit board 200, respectively. DRAM packages 100 connected with the upper and lower surfaces of the printed circuit board 200 may be electrically interconnected via a plurality of via holes 215. The printed circuit board 200 may include a connector 220 to connect the DRAM packages 100 to an external host apparatus through the ball grid array 120, the pads 211 and conductive materials formed therein to transmit and receive data, signals, and/or power.

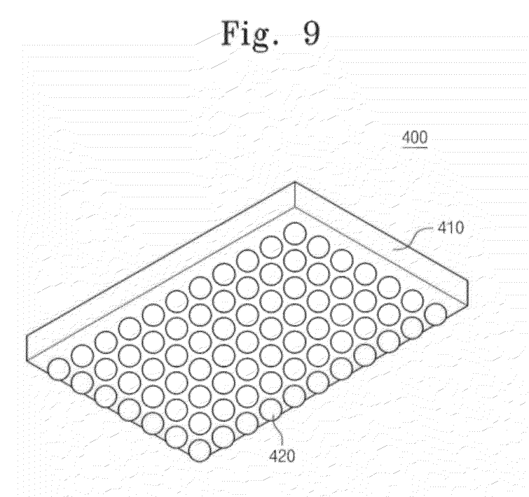

FIG. 9 is a diagram illustrating a DRAM package 400 according to an exemplary embodiment of the inventive concept. Referring to FIG. 9, the DRAM package 400 may include a DRAM package body 410 and a ball grid array (BGA) 420. The ball grid array 420 may be provided at a lower surface of the DRAM package 400.

The ball grid array 420 may include a plurality of solder balls. The plurality of solder balls may connect the DRAM package body 410 and a printed circuit board (not shown). The plurality of solder balls may be formed of a conductive material.

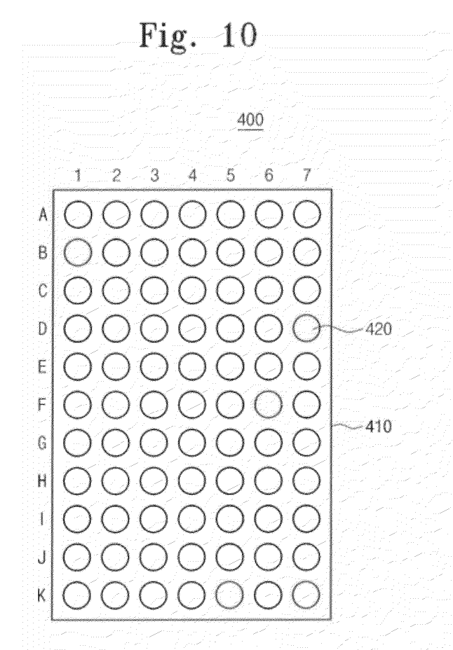

FIG. 10 is a diagram illustrating a lower surface of the DRAM package 400 of FIG. 9. Referring to FIGS. 9 and 10, the ball grid array 420 may include a plurality of solder balls which are arranged at the equal interval along row and columns directions. The ball grid array 420 may include a plurality of solder balls of an 11-by-7 matrix at a lower surface of the DRAM package 400. Eleven (11) rows of the ball grid array 420 may be defined by an A row to a Kth row, respectively, and seven (7) columns thereof may be defined by a first column to a seventh column, respectively.

In this embodiment, a pitch between solder balls of the ball grid array 420 may be 0.8 mm. Solder balls of the ball grid array 420 may be formed within a region of 5.9 mm by 9.1 mm.

As compared with the DRAM package 1000 described with reference to FIGS. 1 and 2, the DRAM package 400 does not include a dummy ball region. The solder balls 420 may be arranged at an equal interval along row and column directions. When an area occupied by the solder balls is reduced, an area occupied by the DRAM package 400 may be reduced.

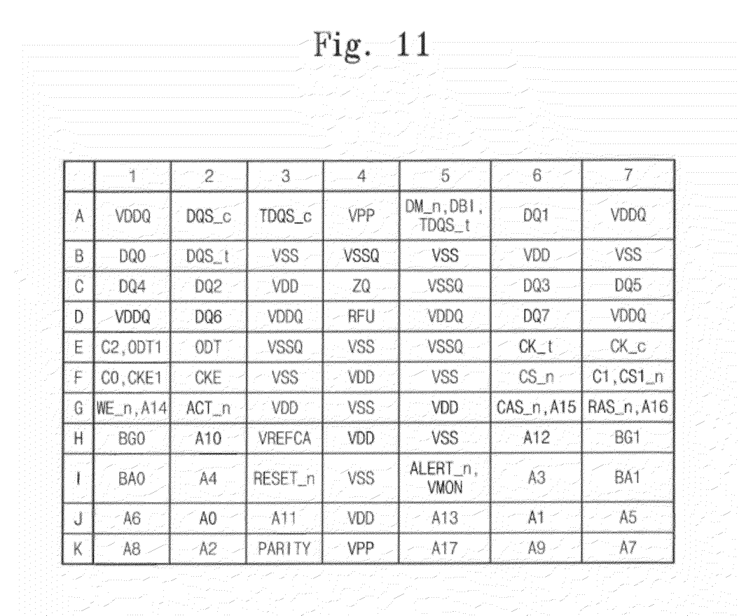

FIG. 11 is a diagram illustrating signals assigned to solder balls of a DRAM package according to an exemplary embodiment of the inventive concept. Referring to FIGS. 9, 10, and 11, solder balls of the A row and the first to fourth columns may be assigned to an input/output power supply voltage VDDQ, a signal DQS_c, a signal TDQS_c, and a high voltage VPP, respectively. When a DRAM package 400 is configured to have the ×4 input/output organization, the signal TDQS_c is not used. A solder ball of the A row and the fifth column may be assigned to signals DM_n, DBI, and TDQS_t. When the DRAM package 400 is configured to have the ×4 input/output organization, the signal TDQS_t is not used. Solder balls of the A row and the sixth and seventh columns may be assigned to a data signal DQ1 and an input/output power supply voltage VDDQ, respectively.

Solder balls of the B row and the first to seventh columns may be assigned to a data signal DQ0, a signal DQS_t, a ground voltage VSS, an input/output power supply voltage VDDQ, a ground voltage VSS, a power supply voltage VDD, and a ground voltage VSS, respectively.

Solder balls of the C row and the first to seventh columns may be assigned to a data signal DQ4, a data signal DQ2, a power supply voltage VDD, a signal ZQ, an input/output ground voltage VSSQ, a data signal DQ3, and a data signal DQ5, respectively.

Solder balls of the D row and the first to seventh columns may be assigned to an input/output power supply voltage VDDQ, a data signal DQ6, an input/output power supply voltage VDDQ, a reserved for future use (RFU), an input/output power supply voltage VDDQ, a data signal DQ7, and an input/output power supply voltage VDDQ, respectively. When the DRAM package 400 is configured to have the ×4 input/output organization, the data signals DQ6 and DQ7 are not used.

A solder ball of the E row and the first column may be assigned to signals C2 and ODT1. Solder balls of the E row and the second to seventh columns may be assigned to a signal ODT, an input/output ground voltage VSSQ, a ground voltage VSS, an input/output power supply voltage VDDQ, a signal CK_t, and a signal CK_c, respectively.

A solder ball of the F row and the first column may be assigned to signals C0 and CKE1. Solder balls of the F row and the second to sixth columns may be assigned to a signal CKE, a ground voltage VSS, a power supply voltage VDD, a ground voltage VSS, and a signal CS_n, respectively. A solder ball of the F row and the seventh column may be assigned to signals C1 and CS1_n.

A solder ball of the G row and the first column may be assigned to a signal WE_n and an address signal A14. Solder balls of the G row and the second to fifth columns may be assigned to a signal ACT_n, a power supply voltage VDD, a ground voltage VSS, and a power supply voltage VDD, respectively. A solder ball of the G row and the sixth column may be assigned to a signal CAS_n and an address signal A15. A solder ball of the G row and the seventh column may be assigned to a signal RAS_n and an address signal A16.

Solder balls of the H row and the first to seventh columns may be assigned to a block group address signal BG0, an address signal A10, a signal VREFCA, a power supply voltage VDD, a ground voltage VSS, an address signal A12, and a block group address signal BG1, respectively.

Solder balls of the I row and the first to fourth columns may be assigned to a block address signal BA0, an address signal A4, a signal RESET_n, and a ground voltage VSS, respectively. A solder ball of the I row and the fifth column may be assigned to a signal ALERT_n and a signal VMON usable to monitor a voltage. Solder balls of the I row and the sixth and seventh columns may be assigned to an address signal A3 and a block address signal BA1, respectively.

Solder balls of the J row and the first to seventh columns may be assigned to an address signal A6, an address signal A0, an address signal A11, a power supply voltage VDD, an address signal A13, an address signal A1, and an address signal A5, respectively.

Solder balls of the K row and the first to seventh columns may be assigned to an address signal A8, an address signal A2, a signal PARITY, a high voltage VPP, an address signal A17, an address signal A9, and an address signal A7, respectively. When the DRAM package 400 is configured to have the ×8 input/output organization, the address signal A17 is not used.

Signals assigned to solder balls in the first and second columns illustrated in FIG. 11 may be identical to those in the second and third columns between the second and eighth rows illustrated in FIG. 3. Signals assigned to solder balls in the sixth and seventh columns illustrated in FIG. 11 may be identical to those in the seventh and eighth columns between the second and eighth rows illustrated in FIG. 3. Signals assigned to solder balls in the first row, the thirteenth row, the first column, and the ninth column illustrated in FIG. 3 may be assigned to solder balls of the third to fifth columns illustrated in FIG. 11. Solder balls identical to each other in FIGS. 3 and 11 may be referred to as a common area or common solder balls in different DRAM packages.

Referring to FIGS. 3 and 11, locations of solder balls assigned to a power may be shifted or changed. A variation of an inner structure of the DRAM package 400 with the shifted locations of solder balls assigned to a power may be little as compared with the shifted locations of solder balls assigned to meaningful signals (major or communication signals), such as data signals and address signals. Accordingly, it is possible to reduce the complexity and cost when a DRAM package 100 of FIG. 3 is changed into a DRAM package 400 of FIGS. 9 to 11, by assigning signals to solder balls as illustrated in FIG. 11.

In a case of the DRAM package 400, 26 solder balls may be assigned to a power, and one solder ball may be a reserved for future use (RFU). The 26 solder balls assigned to a power may include 8 solder balls assigned to a ground voltage VSS, 6 solder balls assigned to a power supply voltage VDD, 4 solder balls assigned to an input/output ground voltage VSSQ, 6 solder balls assigned to an input/output power supply voltage VDDQ, and 2 solder balls assigned to a high voltage VPP. The flexibility (applicability) of the DRAM package 400 may be improved by assigning one solder ball to the RFU.

Arrangement of signals assigned to solder balls in the third to fifth columns of the DRAM package 400 is not limited to FIG. 11.

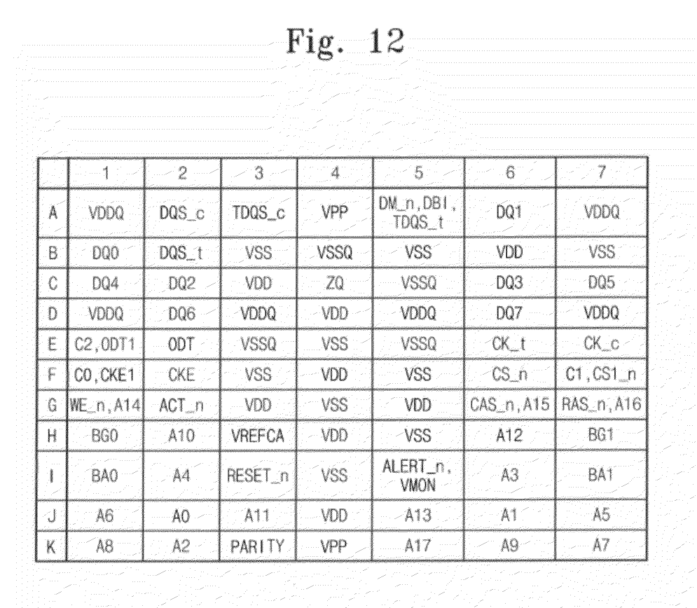

FIG. 12 is a diagram illustrating signals assigned to solder balls of a DRAM package according to another exemplary embodiment of the inventive concept. As compared with FIG. 11, a solder ball of the D row and the fourth column may be assigned to a power supply voltage VDD instead of a reserved for future used (RFU) as V-RFU.

In a case of the DRAM package 400 as illustrated in FIG. 12, 27 solder balls may be assigned to a power. The 23 solder balls assigned to a power may include 8 solder balls assigned to a ground voltage VSS, 7 solder balls assigned to a power supply voltage VDD, 4 solder balls assigned to an input/output ground voltage VSSQ, 6 solder balls assigned to an input/output power supply voltage VDDQ, and 2 solder balls assigned to a high voltage VPP.

As a solder ball is assigned to a power instead of a reserved for future use (RFU), the number of solder balls assigned to a power may be identical to that assigned to a power in FIG. 3. That is, a DRAM package 100 in FIGS. 1 to 3 may be changed into a DRAM package 400 in FIGS. 9, 10, and 12 with the power stability of the DRAM package 400 being maintained.

Arrangement of signals assigned to solder balls in the third to fifth columns of the DRAM package 400 is not limited to FIG. 12.

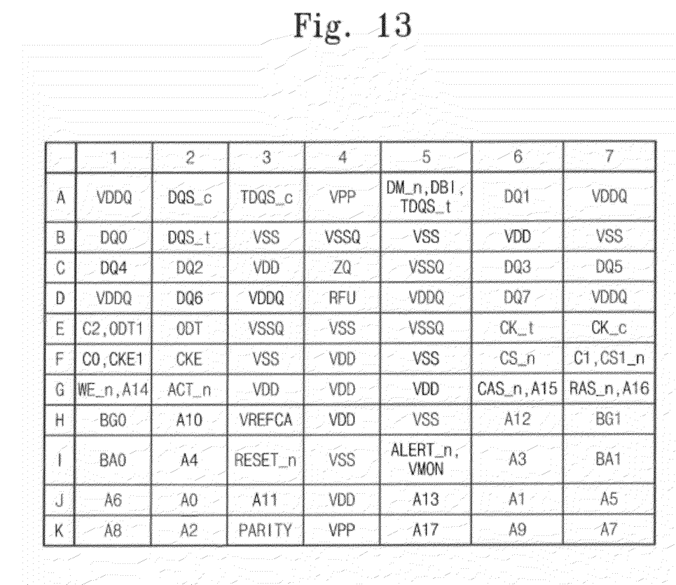

FIG. 13 is a diagram illustrating signals assigned to solder balls of a DRAM package according to an exemplary embodiment of the inventive concept. As compared with FIG. 11, a solder ball of the G row and the fourth column may be assigned to a power supply voltage VDD instead of a ground voltage VSS.

In a case of the DRAM package 400 as illustrated in FIG. 13, 27 solder balls may be assigned to a power, and a solder ball may be assigned to a reserved for future use (RFU). The 22 solder balls assigned to a power may include 7 solder balls assigned to a ground voltage VSS, 8 solder balls assigned to a power supply voltage VDD, 4 solder balls assigned to an input/output ground voltage VSSQ, 6 solder balls assigned to an input/output power supply voltage VDDQ, and 2 solder balls assigned to a high voltage VPP. The flexibility (applicability) of the DRAM package 400 may be improved by assigning one solder ball to the RFU.

As a solder ball is assigned to a power supply voltage instead of a ground voltage VSS, a DRAM package 100 in FIGS. 1 to 3 may be changed into a DRAM package 400 in FIGS. 9, 10, and 12 with the power stability of the DRAM package 400 being maintained.

Arrangement of signals assigned to solder balls in the third to fifth columns of the DRAM package 400 is not limited to the arrangement or assignment of the solder balls with respect to the signals and power as illustrated in FIG. 13.

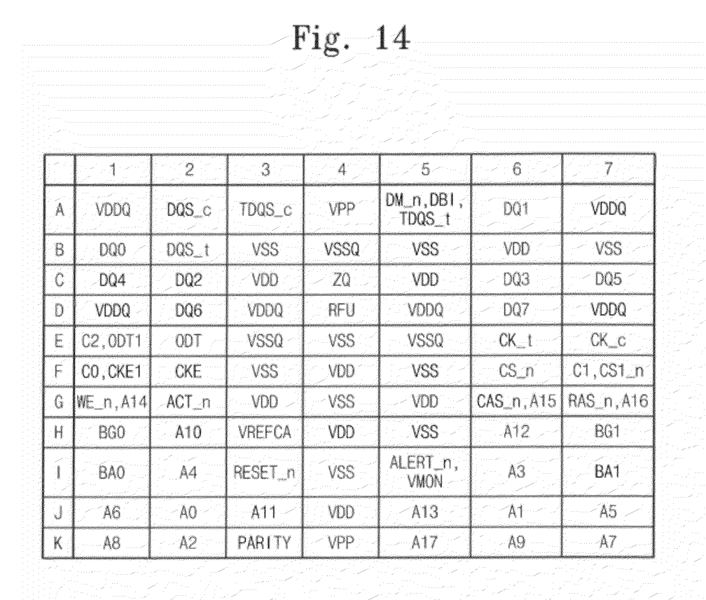

FIG. 14 is a diagram illustrating signals assigned to solder balls of a DRAM package according to still another exemplary embodiment of the inventive concept. As compared with FIG. 11, a solder ball of the C row and the fifth column may be assigned to a power supply voltage VDD instead of an input/output ground voltage VSSQ.

In a case of the DRAM package 400 as illustrated in FIG. 14, 28 solder balls may be assigned to a power, and a solder ball may be assigned to a reserved for future use (RFU). The 28 solder balls assigned to a power may include 9 solder balls assigned to a ground voltage VSS, 8 solder balls assigned to a power supply voltage VDD, 3 solder balls assigned to an input/output ground voltage VSSQ, 6 solder balls assigned to an input/output power supply voltage VDDQ, and 2 solder balls assigned to a high voltage VPP. The flexibility of the DRAM package 400 may be improved by assigning one solder ball to the RFU.

As a solder ball is assigned to a power supply voltage VDD instead of an input/output ground voltage VSSQ, a DRAM package 100 in FIGS. 1 to 3 may be changed into a DRAM package 400 in FIGS. 9, 10, and 12 with the power stability of the DRAM package 400 being maintained.

Arrangement of signals assigned to solder balls in the third to fifth columns of the DRAM package 400 is not limited to the arrangement and assignment of signals and power with respect to the solder balls as illustrated in FIG. 14.

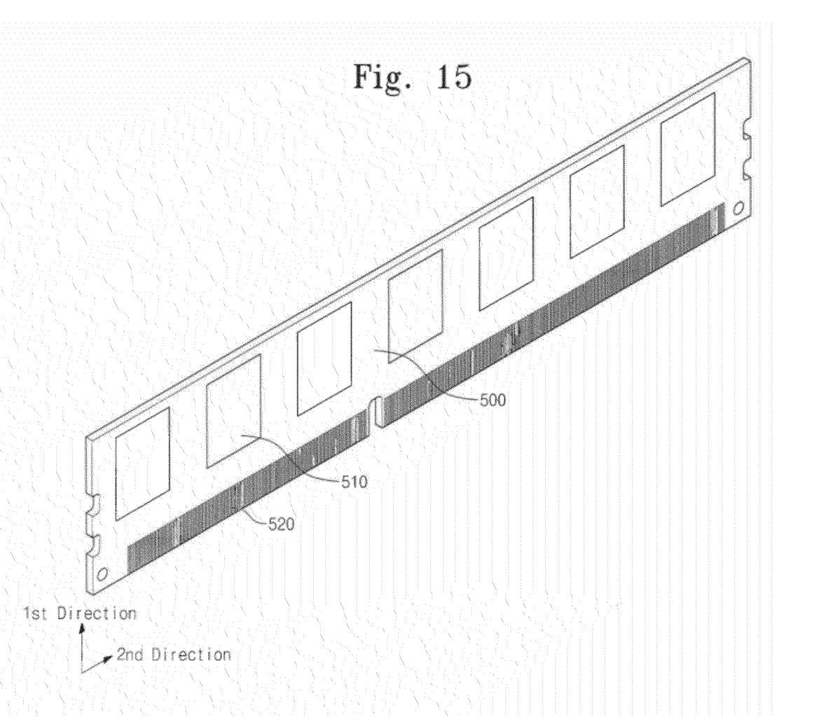

FIG. 15 is a diagram illustrating a printed circuit board 500 corresponding to a DRAM package of FIGS. 9 and 10. Referring to FIGS. 9, 10 and 15, the printed circuit board 500 may include a plurality of DRAM regions 510 and a connector 520.

The DRAM packages 400 according to another exemplary embodiment of the inventive concept may be connected with the plurality of DRAM regions 510, respectively. That is, a plurality of DRAM packages 400 may be connected with the printed circuit board 500. DRAM packages 400 can be provided at upper and lower surfaces of the printed circuit board 500. For example, DRAM packages 400 may be provided at upper and lower surfaces of each of the plurality of DRAM regions 510, respectively.

Each of the plurality of DRAM regions 510 may be connected to the connector 520 via conductive lines (not illustrated). The connector 520 can include a plurality of conductive plates. The connector 520 may be connected to a slot of an external host apparatus such that the conductive plates can be connected to terminals of the slot of the external host apparatus.

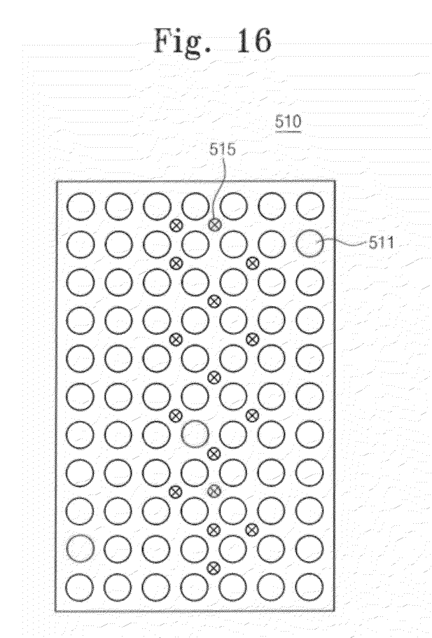

FIG. 16 is a diagram illustrating one of a plurality of DRAM regions 510 of FIG. 15 according to an exemplary embodiment of the inventive concept.

Referring to FIGS. 15 and 16, each DRAM region 510 may include a plurality of pads 511. A plurality of via holes 515 may be formed at spaces among the plurality of pads 511. The plurality of via holes 515 may penetrate a printed circuit board 500 to electrically connect upper and lower surfaces of the printed circuit board 500. Wires for electrically connecting the plurality of via holes 515 and the plurality of pads 511 may be formed at the printed circuit board 500.

If the plurality of via holes 515 is formed between the pads 511, a space (area) for forming the plurality of via holes 515 may not be independently provided from an area of the pads 511. Accordingly, as described in FIGS. 1 to 3, a DRAM package 100 may not be provided with a dummy solder ball region. Further, as described in FIG. 5, a DRAM package 210 may not be provided with a routing region 213.

Locations of via holes and the number of via holes are not limited to those in FIG. 16.

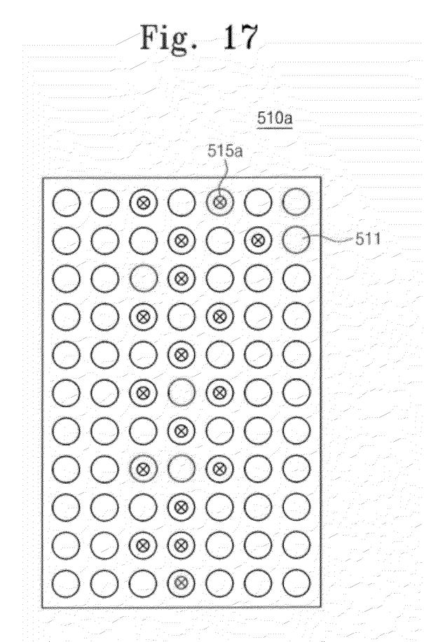

FIG. 17 is a diagram illustrating one of a plurality of DRAM regions 510 of FIG. 15 according to an exemplary embodiment of the inventive concept.

Referring to FIGS. 15 and 17, a DRAM region 510a may include a plurality of pads 511. A plurality of via holes 515a may be formed at regions where the plurality of pads 511 is formed. The plurality of via holes 515a may penetrate the printed circuit board 500 to electrically connect upper and lower surfaces of the printed circuit board 500. Wires for electrically connecting the plurality of via holes 515a and the plurality of pads 511 may be formed at the printed circuit board 500. A conductive material may be disposed in the via holes 515a to connect the DRAM packages to the connector 520 through the solder balls, via holes, and/or pads 511.

If the plurality of via holes 515a is formed at regions where the pads 511 are formed, a space (area) for forming the plurality of via holes 515 may not be independently provided from an area of the pads 511. Accordingly, as described in FIGS. 1 to 3, a DRAM package 100 may not be provided with a dummy solder ball region. Further, as described in FIG. 5, a DRAM package 210 may not be provided with a routing region 213.

Locations of via holes and the number of via holes are not limited to those in FIG. 17.

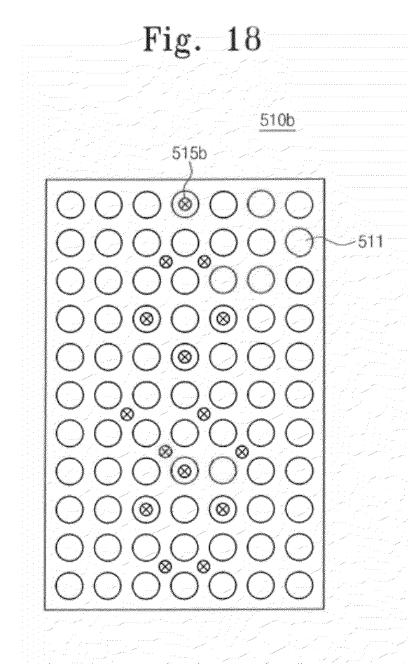

FIG. 18 is a diagram illustrating one of a plurality of DRAM regions in FIG. 15 according to still another exemplary embodiment of the inventive concept.

Referring to FIG. 18, each DRAM region 510b may include a plurality of pads 511. A plurality of via holes 515b may be formed at spaces disposed between the plurality of pads 511 and at regions where the plurality of pads 511 is formed. The plurality of via holes 515b may penetrate a printed circuit board 500 to electrically connect upper and lower surfaces of the printed circuit board 500. Wires for electrically connecting the plurality of via holes 515b and the plurality of pads 511 may be formed at the printed circuit board 500. A conductive material may be filled in or disposed in the via holes 515a to connect the DRAM packages to the connector 520 through the solder balls, via holes, and/or pads 511.

If the plurality of via holes 515a is formed at spaces between the plurality of pads 511 and at regions where the plurality of pads 511 is formed, a space (area) for forming the plurality of via holes 515b may not be provided independently from an area of the pads 511. Accordingly, as described in FIGS. 1 to 3, a DRAM package 100 may not be provided with a dummy solder ball region. Further, as described in FIG. 5, a DRAM package 210 may not be provided with a routing region 213.

Locations of via holes and the number of via holes are not limited to those in FIG. 18.

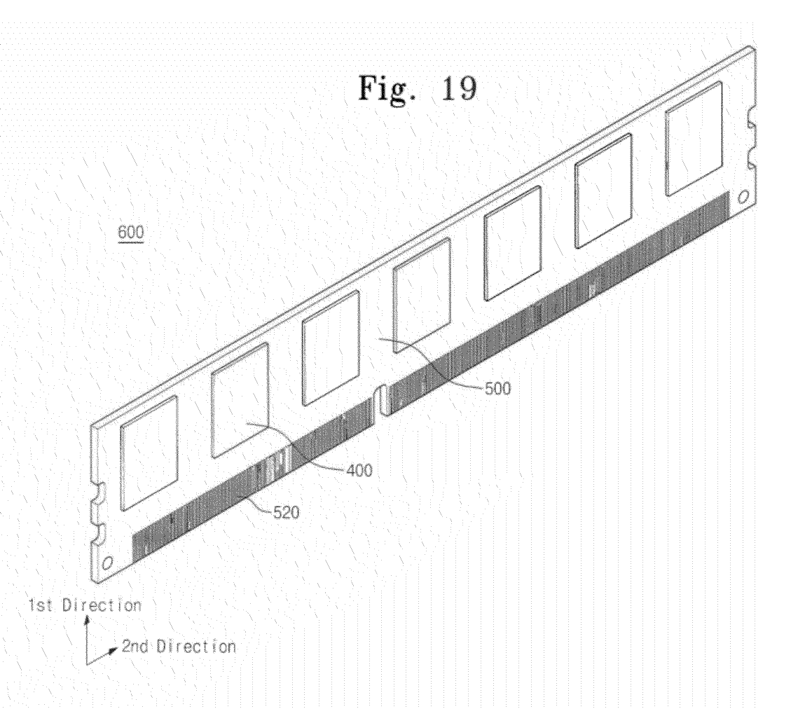

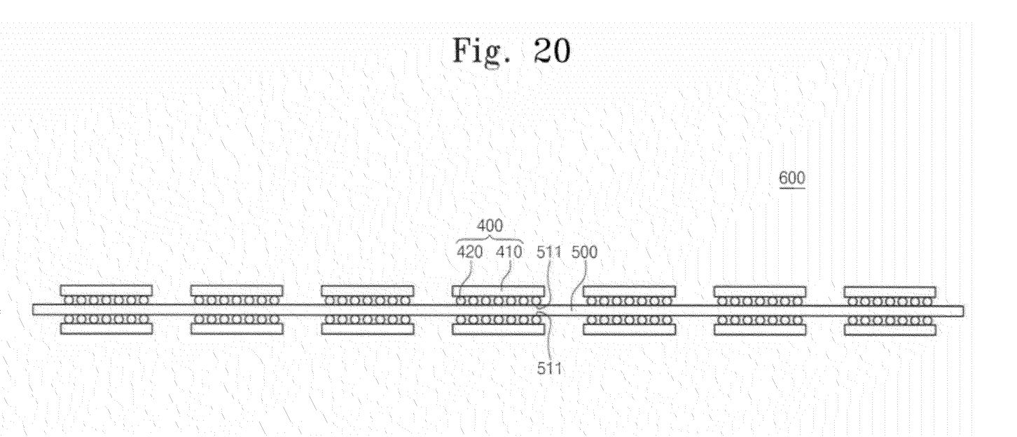

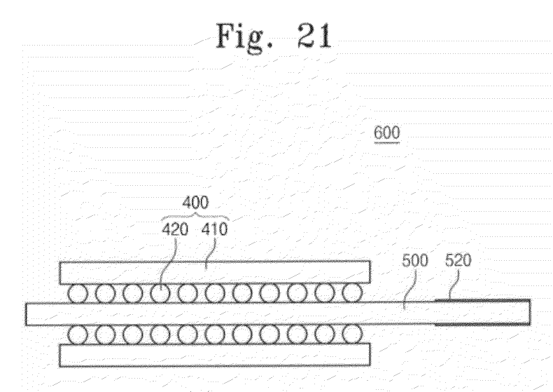

FIGS. 19 to 21 are diagrams illustrating a DRAM module 600, in which DRAM packages and a printed circuit board are connected, according to an exemplary embodiment of the inventive concept. A cross-section view of a DRAM module 600 is illustrated in FIG. 19, a view of the DRAM module 600 in a first direction is illustrated in FIG. 20, and a view of the DRAM module 600 in a second direction is illustrated in FIG. 21.

Referring to FIGS. 19 to 21, a plurality of DRAM packages 400 may be connected at upper and lower surfaces of a printed circuit board 500, respectively. Each DRAM package 400 may include a DRAM package body 410 and a ball grid array 420. The ball grid array 420 may include a plurality of solder balls which may be arranged at a same interval along row and column directions. The plurality of solder balls of the ball grid array 420 may be connected to corresponding pads 511 of the printed circuit board 500, respectively. DRAM packages 400 connected with the upper and lower surfaces of the printed circuit board 500 may be electrically interconnected via a plurality of via holes 515. The via holes 515 can be provided with a conductive wire or filled with a conductive material to connect the DRAM packages 400 to a connector 520. It is possible that the DRAM packages 400 may be connected to corresponding DRAM package through the via holes 515.

If the ball grid array 420 of the DRAM package 400 is configured the same as that in FIGS. 9 to 11, a size of the DRAM package 400 may be reduced as compared with a size of a DRAM package 100 described in FIGS. 1 to 8. Accordingly, in a case of the DRAM module of the same size, an area occupied by the DRAM packages 400 may be reduced. That is, a size of the DRAM module 600 may be reduced.

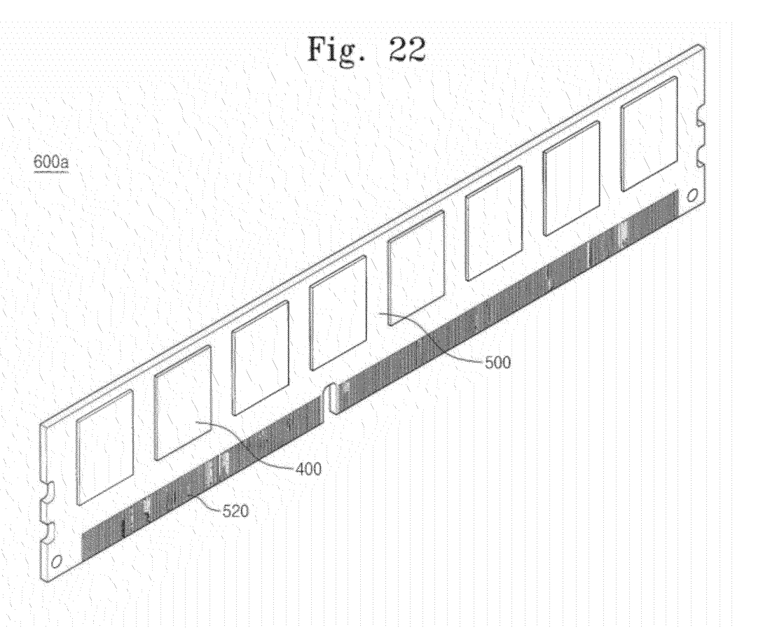

FIG. 22 is a diagram illustrating a DRAM module 600a, in which DRAM packages and a printed circuit board are connected, according to an exemplary embodiment of the inventive concept.

If the ball grid array 420 of a DRAM package 400 is configured the same as that in FIGS. 9 to 11, a size of the DRAM package 400 may be reduced as compared with a size of a DRAM package 100 described in FIGS. 1 to 8. Accordingly, the number of DRAM packages 400 provided on a DRAM module 600a of the same size may increase as compared with a DRAM module 600 described in FIGS. 19 to 21.

DRAM packages 400 may be provided at upper and lower surfaces of a printed circuit board 500, respectively. DRAM packages 400 formed at the upper and lower surfaces of the printed circuit board 500 may be electrically interconnected via a plurality of via holes 515.

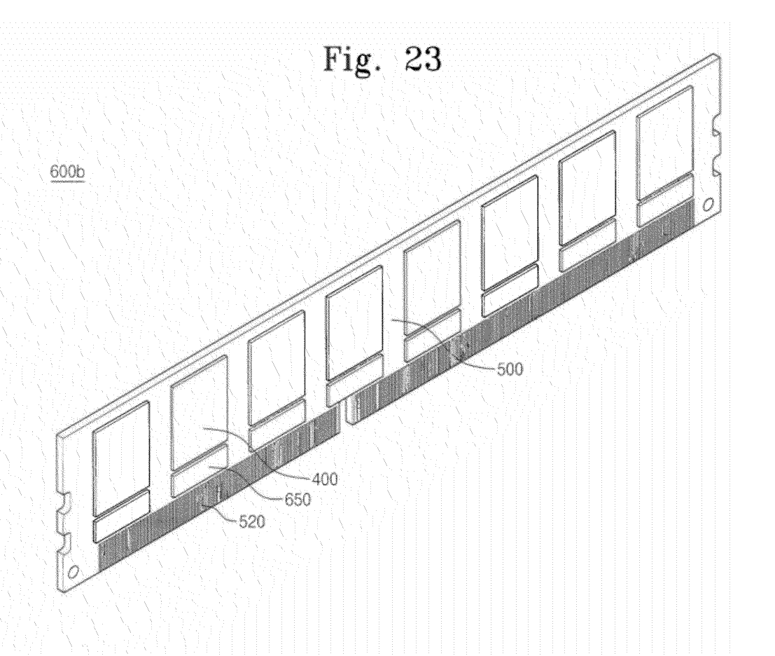

FIG. 23 is a diagram illustrating a DRAM module 600b, in which DRAM packages and a printed circuit board are connected, according to an exemplary embodiment of the inventive concept. As compared with to DRAM module 600a of FIG. 22, a plurality of buffers 650 may be provided. The plurality of buffers 650 may be semiconductor packages each including a ball grid array like the DRAM packages 400. The plurality of buffers 650 may be disposed between the DRAM package 400 and a connector 520.

If the ball grid array 420 of a DRAM package 400 is configured the same as that in FIGS. 9 to 11, a size of the DRAM package 400 may be reduced as compared with a size of a DRAM package 100 described in FIGS. 1 to 8. Accordingly, it is possible to provide the plurality of buffers 650 on the DRAM module 600 of the same size.

DRAM packages 400 may be provided at upper and lower surfaces of a printed circuit board 500 of the DRAM module 600b, respectively. DRAM packages 400 formed at the upper and lower surfaces of the printed circuit board 500 may be electrically interconnected via a plurality of via holes.

The plurality of buffers 650 may be provided at the upper and lower surfaces of the printed circuit board 500 of the DRAM module 600b, respectively. The plurality of buffers 650 formed at the upper and lower surfaces of the printed circuit board 500 may be electrically interconnected via a plurality of via holes. The buffers 650 may be provided to communicate with the corresponding DRAM packages to perform a buffering operation thereof and may be electrically connected between the connector 520 and the DRAM packages.

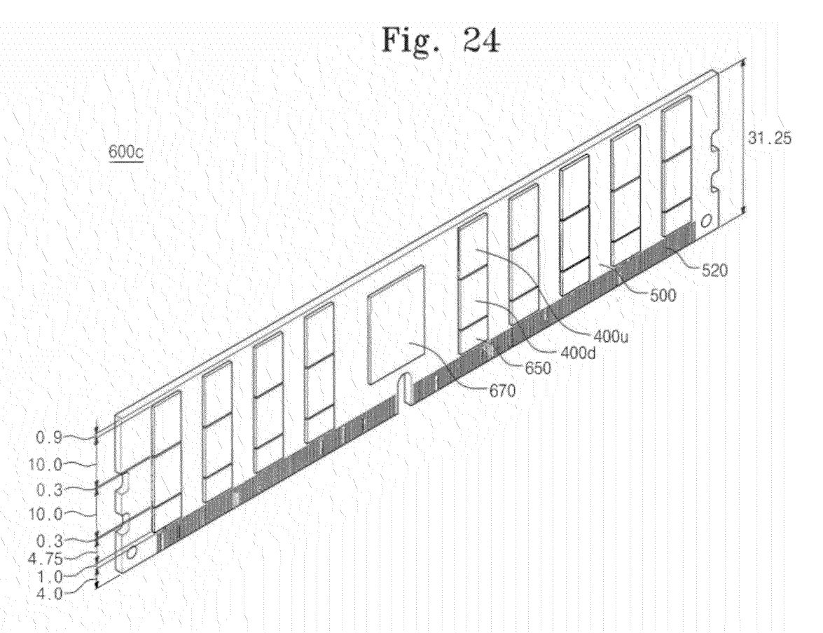

FIG. 24 is a diagram illustrating a DRAM module 600c, in which DRAM packages and a printed circuit board are connected, according to an exemplary embodiment of the inventive concept. As compared with the DRAM module 600b of FIG. 23, upper DRAM packages 400u and lower DRAM package 400d may be provided. A controller 670 may be further provided. A distance between the upper DRAM packages 400u and a side of a printed circuit board 500 may be 0.9 inch. A width of the upper DRAM packages 400u may be 10 inches. A distance between the upper DRAM packages 400u and the lower DRAM packages 400d may be 0.3 inch.

A plurality of buffers 650 may be disposed between the lower DRAM packages 400d and a connector 520. A distance between the lower DRAM packages 400d and the plurality of buffers 650 may be 0.3 inch. A width of the plurality of buffers 650 may be 4.75 inches. A distance between the plurality of buffers 650 and the connector 520 may be 1.0 inch. A width of the connector 520 may be 4.0 inches.

A total width of the DRAM module 600c may be 31.25 inches.

If the ball grid array 420 of a DRAM package 400 is configured the same as that in FIGS. 9 to 11, a size of the DRAM package 400 may be reduced as compared with a size of a DRAM package 100 described in FIGS. 1 to 8. Accordingly, in the DRAM module 600 of the same size, it is possible to provide the upper DRAM packages 400u, the lower DRAM packages 400d, and the plurality of buffers 650.

The upper DRAM packages 400u and the lower DRAM packages 400d may be provided at upper and lower surfaces of a printed circuit board 500 of the DRAM module 600b, respectively. The upper DRAM packages 400u and the lower DRAM packages 400d formed at the upper and lower surfaces of the printed circuit board 500 may be electrically interconnected via a plurality of via holes.

The plurality of buffers 650 may be provided at the upper and lower surfaces of the printed circuit board 500 of the DRAM module 600c, respectively. The plurality of buffers 650 formed at the upper and lower surfaces of the printed circuit board 500 may be electrically interconnected via a plurality of via holes. The buffers 650 may be provided to communicate with the corresponding DRAM packages to perform a buffering operation thereof and may be electrically connected between the connector 520 and the DRAM packages.

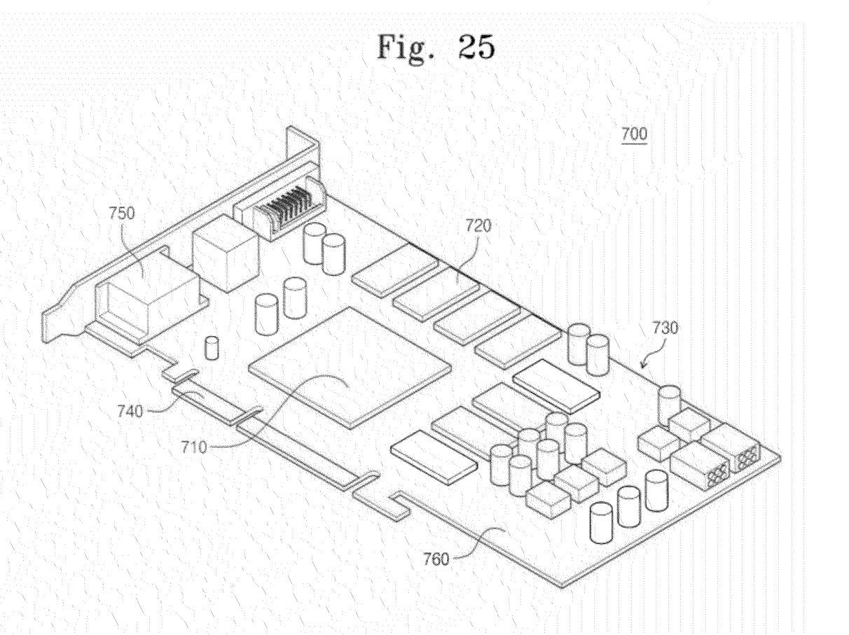

FIG. 25 is a view of an electronic apparatus, for example, a graphic module 700 according to an exemplary embodiment of the inventive concept. Referring to FIG. 25, the graphic module 700 may include a graphic processing unit 710, a plurality of DRAM packages 720, peripheral circuits 730, a connector 740, and communication ports 750, as a function unit of a graphic module.

The graphic processing unit 710 may control an overall operation of the graphic module 700. The graphic processing unit 710 may process graphic data transferred from an external host to output the processed data to a display device such as a monitor.

The DRAM packages 720 may be a working memory of the graphic processing unit 710. The DRAM packages 720 may be graphic DRAM packages. The DRAM packages 720 may include a plurality of solder balls arranged in the equal interval along row and column directions. Accordingly, it is possible to reduce an area occupied by the DRAM packages 720 and a size of the graphic module 700. Further, the number of DRAM packages provided at the graphic module 700 may increase, and buffers may be added.

The peripheral circuits 730 may include constituent elements needed for an operation of the graphic module 700. Exemplarily, the peripheral circuits 730 may include constituent elements such as resistors, inductors, capacitors, and the like. The peripheral circuits may be well known, and thus detail descriptions thereof will be omitted.

The connector 740 may be connected with an external host apparatus. The graphic module 700 may communicate with the external host apparatus via the connector 740. The graphic module 700 may receive data or signals from the external host apparatus through the connector 740, store the received data or signals in the DRAM packages, process or perform a corresponding operation on the received data or signals using the data and signals, store the processed data or signals in the DRAM packages, and output the processed data or signals to a display (monitor) apparatus to display an image corresponding to the output data or signals.

The communication port 750 may be connected with an external device communicating with the graphic module 700. For example, the communication port 750 may be connected with a monitor controlled by the graphic module 700 to output an image or sound according to data or signals provided by the graphic module 700. The communication port 750 can be connected with another graphic module communicating with the graphic module 700. When the monitor is a touch pad, the graphic module 700 may receive a command corresponding to the displayed image through the touch pad and the communication port 750 and perform an operation according to the input command.

The graphic module 700 may include a circuit board 760 formed with conductive lines to electrically connect the graphic processing module 710, the DRAM packages 720, the peripheral circuits 730, the communication port 750, and the connector 740 which are disposed thereon.

The DRAM package 720 and the circuit board 760 may have similar to or the same structures and may be connected to each other, as illustrated in FIGS. 1 through 24.

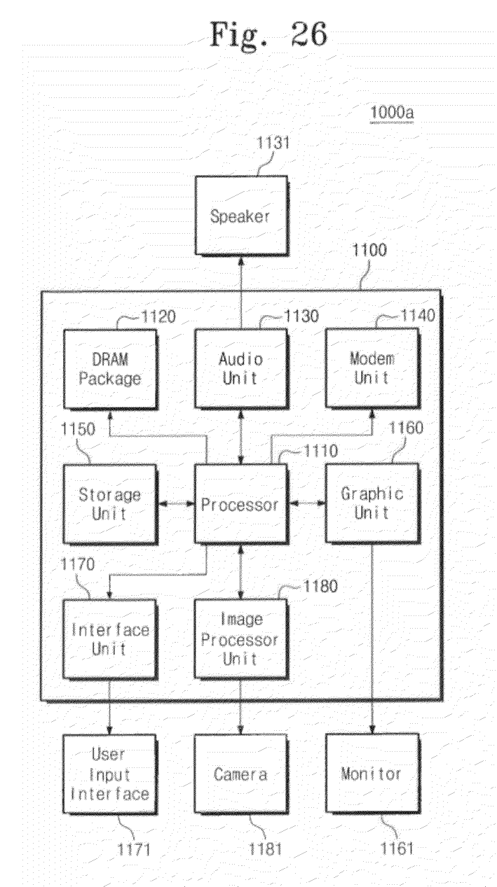

FIG. 26 is a block diagram an electronic apparatus, for example, a multimedia device 1000a including a DRAM package according to an exemplary embodiment of the inventive concept. Referring to FIG. 26, the multimedia device 1000a may include a controller 1100, a speaker 1131, a user input interface 1171, a camera 1181, and/or a monitor 1161. The controller 1100 may include a processor 1110, a DRAM package 1120, an audio unit 1130, a modem unit 1140, a storage unit 1150, a graphic unit 1160, an interface unit 1170, and/or an image processor unit 1180, as a function unit of an electronic apparatus.

The multimedia device 100a may have a single housing to accommodate the above-described components. That is, the controller 1100, speaker 1131, user input interface 1171, camera, and/or monitor 1161 may be disposed in or on the single housing. However, it is possible that one of the speaker 1131, user input interface 1171, camera 1181, and monitor 1161 may be connected to the controller 1100 of the single housing through a wired or wireless channel or a wireless communication method and structure.

The processor 1110 of the controller 1100 may be configured to control an overall operation of the multimedia device 1000a.

The DRAM package 1120 may operate according to the control of the processor 1110. The DRAM package 1120 may be a working memory of the processor 1110. As described in FIGS. 9 to 11, the DRAM package 1120 may include a plurality of solder balls arranged at the equal interval along row and column directions. Accordingly, an area occupied by the DRAM package 1120 may be reduced, so that a size of the multimedia device 1000a is reduced. Further, the number of DRAM packages 1120 provided at the multimedia device 1000a may increase, and a buffer may be added at the DRAM package 1210.

There is exemplarily illustrated the case that the multimedia device 1000a includes one DRAM package. However, the number of DRAM packages provided in the multimedia device 1000a may not be limited thereto.

The audio unit 1130 may operate according to the control of the processor 1110. The audio unit 1130 may process an audio signal to output the processed audio signal to the speaker 1131. The speaker 1131 may be connected to a terminal of the audio unit 1130, and the terminal of the audio unit 1130 may be formed on the signal housing to be connected to the speaker 1131. It is possible that the speaker 1131 can be wirelessly connected to the audio unit 1130. In this case, the speaker 1131 and the audio unit 1130 may have a wireless connection interface to wirelessly transmit data or signals between the speaker 1131 and the audio unit 1130.

The modem unit 1140 may operate as a communication unit according to the control of the processor 1110. The modem unit 1140 may communicate with an external device via a wireless or wire channel. The modem unit 1140 may communicate with an external device according to wireless protocols such as CDMA (Code Division Multiple Access), GSM (Global System for Mobile communications), CDMA 2000, WCDMA (Wideband Code Division Multiple Access), LTE (Long Term Evolution), WiBro (Wireless Broadband Internet), Mobile WiMAX (World Interoperability), WiFi, and the like. The modem unit 1140 may communicate with an external device according to wire protocols such as ADSL (Asymmetric Digital Subscriber Line), VDSL (Very high data rate Digital Subscriber Line), ISDN (Integrated Services Digital Network), and the like.

The storage unit 1150 may operate according to the control of the processor 1110. The storage unit 1150 may be a nonvolatile storage unit. The storage unit 1150 may include nonvolatile memories such as an EEPROM (Electrically Erasable and Programmable ROM), a flash memory, a PRAM, an MRAM, an RRAM, a FRAM, and the like. The storage unit 1100 may include a hard disk drive (HDD), a solid state drive (SSD), and the like. The storage unit 1150 may include a hard disk drive (HDD), a solid state drive (SSD), and the like.

The graphic unit 1160 may operate according to the control of the processor 1110. The graphic unit 1160 may process graphic data. The graphic unit 1160 may control the monitor 1161 to output an image according to the processed data.

The interface unit 1170 may control the user input interface 1171. The interface unit 1170 may receive a signal from a user via the user input interface 1171. The interface unit 1170 may process a signal input via the user input interface 1171 to send the processed signal input to the processor 1110. The user input interface 1171 may include a microphone, a touch pad, a touch screen, a button, a mouse, a keyboard, and the like. The user input interface 1171 may be formed with the monitor as a single unit to display an image and/or to receive a signal input from a user.

The image processor unit 1180 may operate according to the control of the processor 1110. The image processor unit 1180 may process data taken via the camera 1181. The image processor unit 1180 may process image data or picture data taken via the camera 1181. The process data may be displayed on the monitor 1161 and an audio signal may be processed or output through the audio unit 1130 and/or the speaker 1131.

In an exemplary embodiment, the processor 1110, the DRAM package 1120, the audio unit 1130, the modem unit 1140, the storage unit 1150, the graphic unit 1160, the interface unit 1170, and the image processor unit 1180 may be formed on a printed circuit board 1100. The DRAM package 1120 may be an independent package formed on the printed circuit board 1100. As described with reference to FIGS. 9 to 11, the DRAM package 1120 may include a plurality of solder balls arranged at the equal interval along row and column directions.

A combination of at least two of the processor 1110, the audio unit 1130, the modem unit 1140, the storage unit 1150, the graphic unit 1160, the interface unit 1170, and the image processor unit 1180 may constitute a system-on-chip.

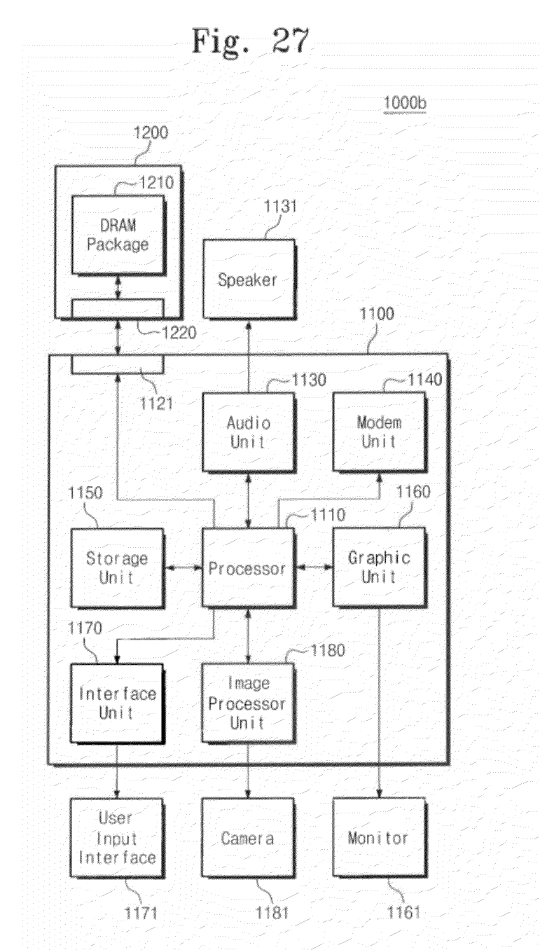

FIG. 27 is a block diagram illustrating a multimedia device 1000b including a DRAM package according to an exemplary embodiment of the inventive concept. Referring to FIG. 27, a multimedia device 1000b may include a controller 1100, a speaker 1131, a user input interface 1171, a camera, a monitor 1161, and/or a semiconductor chip module, for example, a DRAM module 1200. The controller 1100 may include a processor 1110, an audio unit 1130, a modem unit 1140, a storage unit 1150, a graphic unit 1160, an interface unit 1170, and/or an image processor unit 1180, a function unit of the multimedia device 1000b.

The processor 1110, the audio unit 1130, the modem unit 1140, the storage unit 1150, the graphic unit 1160, the interface unit 1170, and the image processor unit 1180 may be formed on a printed circuit board 1100. A combination of at least two of the processor 1110, the audio unit 1130, the modem unit 1140, the storage unit 1150, the graphic unit 1160, the interface unit 1170, and the image processor unit 1180 may constitute a system-on-chip.

A connector 1121 may be provided at the printed circuit board 1100. The connector 1121 may be electrically connected with the processor 1100.

The DRAM module 1200 may include a DRAM package 1210 and a connector 1220. The DRAM module 1210 and the connector 1220 may be formed on one printed circuit board (not shown).

As described in FIGS. 9 to 11, the DRAM package 1210 may include a plurality of solder balls arranged at the equal interval along row and column directions. Accordingly, an area occupied by the DRAM package 1210 may be reduced, so that a size of the multimedia device 1000b is reduced. Further, the number of DRAM packages 1210 provided at the multimedia device 1000b may increase, and a buffer may be added at the DRAM package 1200.

The connector 1220 may be electrically connected with the DRAM package 1210. The connector 1220 may be connected with the connector 1121 of the printed circuit board 1100.

There is exemplarily illustrated the case that the DRAM module 1200 includes one DRAM package 1210. However, the number of DRAM packages 1210 provided in the DRAM module 1200 may not be limited thereto.

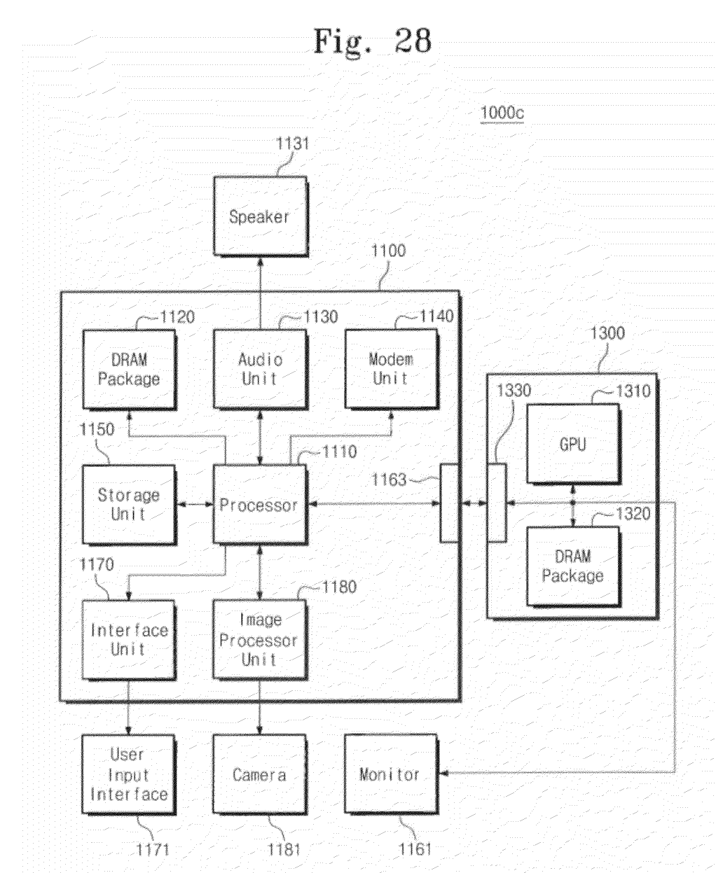

FIG. 28 is a block diagram a multimedia device 1000c including DRAM packages according to still another exemplary embodiment of the inventive concept. Referring to FIG. 28, the multimedia device 1000c may include a controller 1100, a speaker 1131, a user input interface 1171, a camera 1181, a monitor 1161, and/or a graphic module 1300. The controller 1100 may include a processor 1110, a DRAM package 1120, an audio unit 1130, a modem unit 1140, a storage unit 1150, an interface unit 1170, and/or an image processor unit 1180, a function unit of the multimedia device 1000c.

The processor 1110, the DRAM package 1120, the audio unit 1130, the modem unit 1140, the storage unit 1150, the interface unit 1170, and the image processor unit 1180 may be formed on a printed circuit board 1100.

As described in FIGS. 9 to 11, the DRAM package 1210 may include a plurality of solder balls arranged in the equal interval along row and column directions. Accordingly, an area occupied by the DRAM package 1210 may be reduced, so that a size of the multimedia device 1000b is reduced. Further, the number of DRAM packages 1210 provided at the multimedia device 1000b may increase, and a buffer may be added at the DRAM package 1200.

The DRAM package 1120 may be an independent package formed at the printed circuit board 1100. As described in FIGS. 9 to 11, the DRAM package 1120 may include a plurality of solder balls arranged in the equal interval along row and column directions. Accordingly, an area occupied by the DRAM package 1120 may be reduced, so that a size of the multimedia device 1000c is reduced. Further, the number of DRAM packages 1120 provided at the multimedia device 1000c may increase, and a buffer may be added at the multimedia device 1000c.

There is exemplarily illustrated the case that the multimedia device 1000c includes one DRAM package 1120. However, the number of DRAM packages 1120 provided in the multimedia device 1000c may not be limited thereto.

A combination of at least two of the processor 1110, the audio unit 1130, the modem unit 1140, the storage unit 1150, the graphic unit 1160, the interface unit 1170, and the image processor unit 1180 may constitute a system-on-chip.

A connector 1163 may be provided at the printed circuit board 1100. The connector 1163 may be electrically connected with the processor 1100.

The graphic module 1300 may include a graphic processing unit 1310, a DRAM package 1320, and a connector 1330. The graphic processing unit 1310, the DRAM package 1320, and the connector 1330 may be formed on one printed circuit board (not illustrated). As described in FIGS. 9 to 11, the DRAM package 1320 may include a plurality of solder balls arranged at the equal interval along row and column directions. The graphic processing unit 1310 may include a plurality of solder balls arranged in the equal interval along row and column directions. Accordingly, an area occupied by the DRAM package 1320 may be reduced, so that sizes of the multimedia device 1000c and the graphic module 1300 are reduced. Further, the number of DRAM packages 1320 provided at the graphic module 1300 may increase, and a buffer may be added at the graphic module 1300.

The connector 1330 may electrically connect the graphic processing unit 1310 and the DRAM package 1320. The connector 1330 may be connected with a connector 1163 of a printed circuit board of the controller 1100.

The graphic module 1300 may control the monitor 1161. The graphic module 1300 may output an image via the monitor 1161. The graphic module 1300 may be a graphic module 700 described with reference to FIG. 19.

There is exemplarily illustrated the case that the graphic module 1300 includes one DRAM package 1320. However, the number of DRAM packages 1320 provided in the graphic module 1300 is not limited thereto.

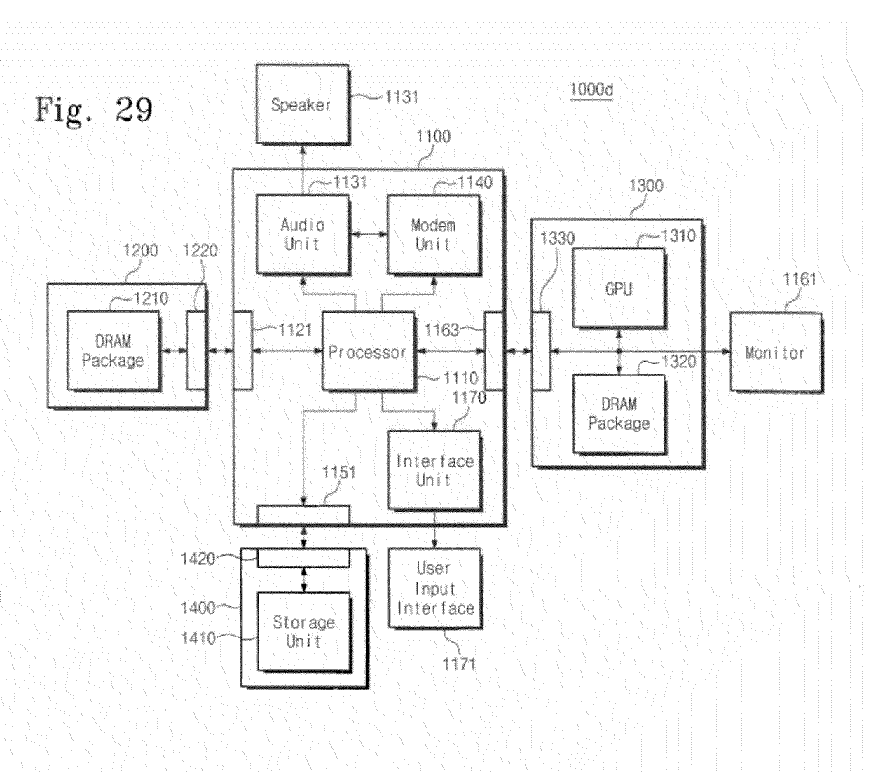

FIG. 29 is a block diagram a multimedia device 1000d including DRAM packages according to an exemplary embodiment of the inventive concept. Referring to FIG. 29, the multimedia device 1000d may include a controller 1100, a DRAM module 1200, a graphic module 1300, a storage module 1400, a speaker 1131, a monitor 1161, and/or a user interface 1171. The controller 1100 may include a processor 1110, an audio unit 1130, a modem unit 1140, and/or an interface unit 1170, as a function unit of the multimedia device 1000d.

The processor 1110, the audio unit 1130, the modem unit 1140, and the interface unit 1170 may be formed on a printed circuit board of the controller 1100. A combination of at least two of the processor 1110, the audio unit 1130, the modem unit 1140, and the interface unit 1170 may constitute a system-on-chip.

Connectors 1121, 1151, and 1163 may be provided at the printed circuit board of the controller 1100. The connectors 1121, 1151, and 1163 may be electrically connected with the processor 1110.

The DRAM module 1200 may include a DRAM package 1210 and a connector 1220. The DRAM package 1210 and the connector 1220 may be formed at one printed circuit board (not shown). As described in FIGS. 9 to 11, the DRAM package 1210 may include a plurality of solder balls arranged in the equal interval along row and column directions. Accordingly, an area occupied by the DRAM package 1210 may be reduced, so that sizes of the multimedia device 1000d and the DRAM module 1200 are reduced. Further, the number of DRAM packages 1210 provided in the DRAM module 1200 may increase, and a buffer may be added in the DRAM module 1200.

The connector 1220 may be electrically connected with the DRAM package 1210. The connector 1220 may be connected with the connector 1221 of the printed circuit board of the controller 1100.

There is exemplarily illustrated the case that the DRAM module 1200 includes one DRAM package 1210. However, the number of DRAM packages included in the DRAM module 1200 is not limited thereto.

The graphic module 1300 may include a graphic processing unit 1310, a DRAM package 1320, and a connector 1330. The graphic processing unit 1310, the DRAM package 1320, and the connector 1330 may be formed on one printed circuit board (not shown). As described in FIGS. 9 to 11, the DRAM package 1320 may include a plurality of solder balls arranged in the equal interval along row and column directions. The graphic processing unit 1310 may include a plurality of solder balls arranged in the equal interval along row and column directions. Accordingly, an area occupied by the DRAM package 1320 may be reduced, so that sizes of the multimedia device 1000d and the graphic module 1300 are reduced. Further, the number of DRAM packages included in the graphic module 1300 may increase, and a buffer may be added in the graphic module 1300.

The connector 1330 may electrically connect the graphic processing unit 1310 and the DRAM package 1320. The connector 1330 may be connected with the connector 1163 of the printed circuit board of the controller 1100.

The graphic module 1300 may control the monitor 1161. The graphic module 1300 may output an image via the monitor 1161. The graphic module 1300 may be a graphic module 700 described with reference to FIG. 19.

There is exemplarily illustrated the case that the graphic module 1300 includes one DRAM package 1320. However, the number of DRAM packages provided in the graphic module 1300 is not limited thereto.

The storage module 1400 may include a storage unit 1410 and a connector 1420. The storage unit 1410 may be a nonvolatile storage unit. The storage unit 1410 may include nonvolatile memories such as an EEPROM (Electrically Erasable and Programmable ROM), a flash memory, a PRAM, an MRAM, an RRAM, a FRAM, and the like.

The connector 1420 may be electrically connected with the storage unit 1410. The connector 1420 may be connected with the connector 1151 of the printed circuit board of the controller 1100.

The storage module 1400 may include HDD (Hard Disk Drive) or SSD (Solid State Drive).

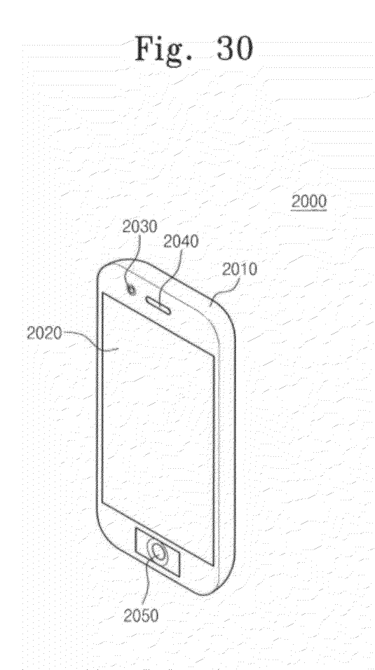

FIG. 30 is a diagram illustrating a mobile device, for example, a smart phone 2000, according to an exemplary embodiment of the inventive concept. Referring to FIG. 30, the smart phone 2000 may include an external case 2010, a screen 2020, a camera 2030, a speaker 2040, and an operating button 2050, as a function unit of the mobile device.

The screen 2020 may form the monitor 1161 described with reference to FIGS. 26 to 29. The camera 2030 may be a camera described with reference to FIGS. 26 to 29. The operating button 2050 may form the user input interface 1171 described with reference to FIGS. 26 to 29. If the screen 2020 is a touch screen, it may form the user input interface 1171. The speaker 2040 may correspond to the speaker 1131 described with reference to FIGS. 26 to 29.

The smart phone 2000 may correspond to one of multimedia devices 1000a to 1000d described with reference to FIGS. 26 to 29, respectively. The smart phone 2000 may include at least one DRAM package which includes a plurality of solder balls arranged at the equal interval along row and column directions as illustrated in FIGS. 1 through 24. Accordingly, an area of the smart phone 2000 may be reduced. Further, the number of DRAM packages included in the smart phone 2000 may increase, and a buffer may be added.

A speaker 1131 and a user input interface 1171 may be further provided on at least one of rear, upper, lower, and lateral sides of the smart phone 2000. Further, the speaker 1131, the monitor 1161, the user input interface 1171, and the camera 1181 may be further provided as accessories connected with the smart phone 2000.

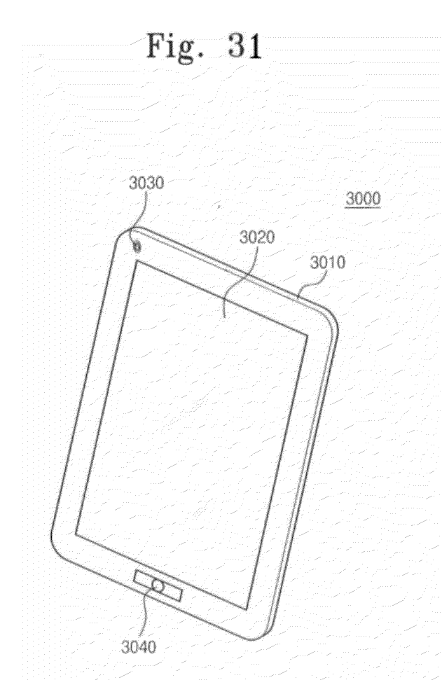

FIG. 31 is a diagram illustrating a tablet computer 3000 according to an exemplary embodiment of the inventive concept. Referring to FIG. 31, the tablet computer 3000 may include an external case 3010, a screen 3020, a camera 3030, and an operating button 3040, as a function unit of the tablet computer 3000.

The screen 3020 may form a monitor 1161 described with reference to FIGS. 26 to 29. The camera 3030 may be the camera 1181 described with reference to FIGS. 26 to 29. The operating button 3040 may form the user input interface 1171 described with reference to FIGS. 26 to 29. If the screen 3020 is a touch screen, it may form the user input interface 1171. The tablet computer 300 may further include the speaker 1131 described with reference to FIGS. 26 to 29.

The tablet computer 3000 may correspond to one of multimedia devices 1000a to 1000d described with reference to FIGS. 26 to 29, respectively. The tablet computer 3000 may include at least one DRAM package which includes a plurality of solder balls arranged at the equal interval along row and column directions as illustrated in FIGS. 1 through 24. Accordingly, an area of the tablet computer 3000 may be reduced. Further, the number of DRAM packages included in the tablet computer 3000 may increase, and a buffer may be added.

A speaker 1131 and a user input interface 1171 may be further provided on at least one of rear, upper, lower, and lateral sides of the tablet computer 3000. Further, the speaker 1131, the monitor 1161, the user input interface 1171, and the camera 1181 may be further provided as accessories connected with the tablet computer 3000.

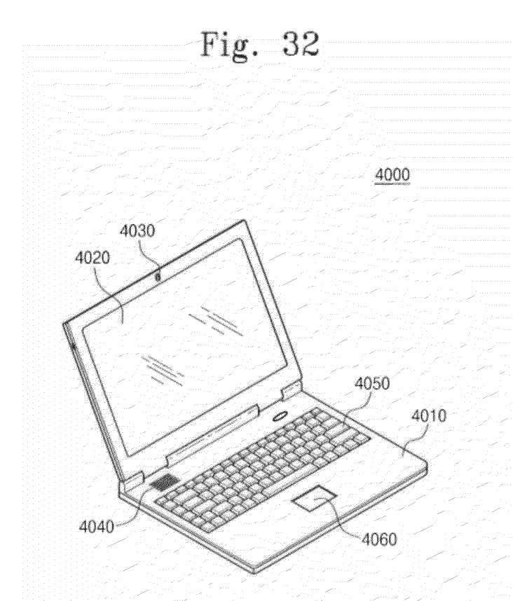

FIG. 32 is a diagram illustrating a mobile computer 4000 according to an exemplary embodiment of the inventive concept. Referring to FIG. 32, the mobile computer 4000 may include an external case 4010, a screen 4020, a camera 4030, a speaker 4040, a keyboard 4050, and a touch pad 4060, a function unit of the mobile computer 4000.

The screen 4020 may form the monitor 1161 described with reference to FIGS. 26 to 29. The camera 4030 may be the camera 1181 described with reference to FIGS. 26 to 29. The keyboard 4050 and the touch pad 4060 may form the user input interface 1171 described with reference to FIGS. 26 to 29. If the screen 4020 is a touch screen, it may form the user input interface 1171. The speaker 4040 may correspond to the speaker 1131 described with reference to FIGS. 26 to 29.

The mobile computer 4000 may correspond to one of multimedia devices 1000a to 1000d described with reference to FIGS. 26 to 29, respectively. The mobile computer 4000 may include at least one DRAM package which includes a plurality of solder balls arranged at the equal interval along row and column directions as illustrated in FIGS. 1 through 24. Accordingly, an area of the mobile computer 4000 may be reduced. Further, the number of DRAM packages included in the mobile computer 4000 may increase, and a buffer may be added.

The mobile computer 4000 may be a notebook computer or a netbook. A speaker 1131 and a user input interface 1171 may be further provided on at least one of rear, upper, lower, and lateral sides of the mobile computer 4000. Further, the speaker 1131, the monitor 1161, the user input interface 1171, and the camera 1181 may be further provided as accessories connected with the mobile computer 4000.

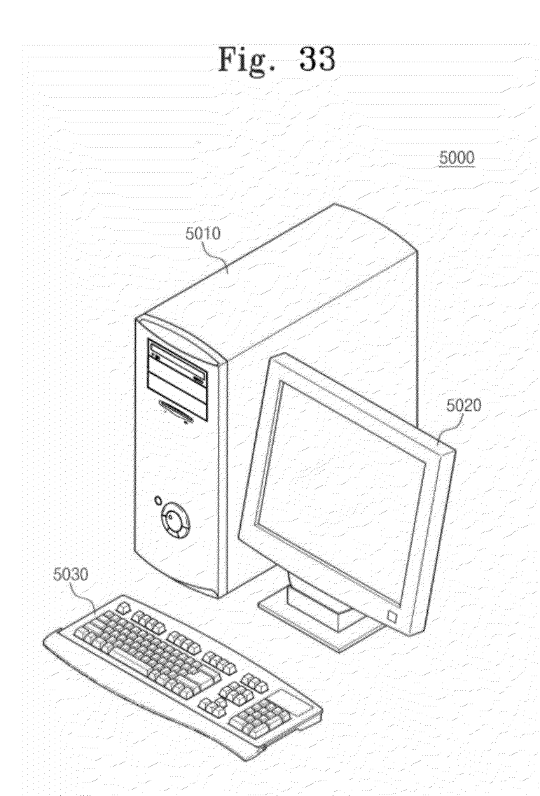

FIG. 33 is a diagram illustrating a computer apparatus 5000 according to an exemplary embodiment of the inventive concept. Referring to FIG. 33, the computer apparatus 5000 may include a body 5010, a monitor 5020, and a keyboard 5030, as a function unit of the computer apparatus 5000.

The monitor 5020 may be the monitor 1161 described with reference to FIGS. 26 to 29. The keyboard 5030 may form the user input interface 1171 described with reference to FIGS. 26 to 29. If the monitor 5020 is a touch screen, it may form the user input interface 1171.

The computer apparatus 5000 may correspond to one of multimedia devices 1000a to 1000d described with reference to FIGS. 26 to 29, respectively. The computer apparatus 5000 may include at least one DRAM package which includes a plurality of solder balls arranged at the equal interval along row and column directions as illustrated in FIGS. 1 through 24. Accordingly, an area of the computer 5000 may be reduced. Further, the number of DRAM packages included in the computer 5000 may increase, and a buffer may be added.

A speaker 1131, a user input interface 1171, and a camera 1181 may be further provided on at least one of rear, upper, lower, and lateral sides of the computer 5000. Further, the speaker 1131, the monitor 1161, the user input interface 1171, and the camera 1181 may be further provided as accessories connected with the computer 5000.

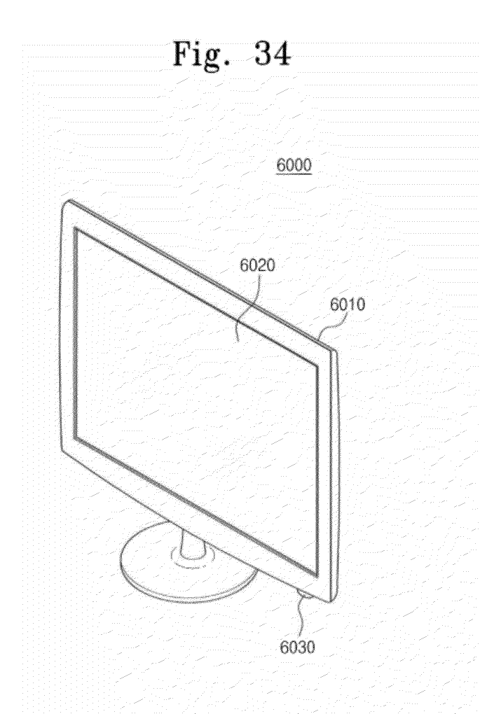

FIG. 34 is a diagram illustrating a television apparatus 6000 according to an exemplary embodiment of the inventive concept. Referring to FIG. 34, the television 6000 may include an external case 6010, a screen 6020, and an operating button 6030 as a function unit of the television apparatus 6000.

The screen 6020 may form the monitor 1161 described with reference to FIGS. 26 to 29. The operating button 6030 may form the user input interface 1171 described with reference to FIGS. 26 to 29. If the screen 6020 is a touch screen, it may form the user input interface 1171.

The television apparatus 6000 may correspond to one of multimedia devices 1000a to 1000d described with reference to FIGS. 26 to 29, respectively. The television 6000 apparatus may include at least one DRAM package which includes a plurality of solder balls arranged at the equal interval along row and column directions as illustrated in FIGS. 1 through 24. Accordingly, an area of the television 6000 may be reduced. Further, the number of DRAM packages included in the television 6000 may increase, and a buffer may be added.

The television apparatus 6000 may be a three-dimensional (3D) television apparatus or a smart television apparatus. A speaker 1131 and a user input interface 1171 may be further provided on at least one of rear, upper, lower, and lateral sides of the television 6000. Further, the speaker 1131, the monitor 1161, the user input interface 1171, and the camera 1181 may be further provided as accessories connected with the television 6000. Exemplarily, a remote controller communicating with the television 6000 may be further provided as the user input interface 1171.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A DRAM package comprising:
a DRAM package body; and
a ball grid array formed at a lower surface of the DRAM package body, the ball grid array including a plurality of solder balls arranged at an equal interval along row and column directions thereof.

2. The DRAM package of claim 1, wherein the plurality of solder balls are arranged in an 11-by-7 matrix.

3. The DRAM package of claim 2, wherein the plurality of solder balls include 22 solder balls assigned to a power and one solder ball assigned to a reserved for future use.

4. The DRAM package of claim 3, wherein the power assigned to the 22 solder balls includes a high voltage, a power supply voltage, a ground voltage, an input/output power supply voltage, and an input/output ground voltage.

5. The DRAM package of claim 3, wherein the 22 solder balls assigned to the power include 2 solder balls assigned to a high voltage, 6 solder balls assigned to a power supply voltage, 8 solder balls assigned to a ground voltage, 2 solder balls assigned to an input/output power supply voltage, and 4 solder balls assigned to an input/output ground voltage.

6. The DRAM package of claim 3, wherein the 22 solder balls assigned to the power include 2 solder balls assigned to a high voltage, 7 solder balls assigned to a power supply voltage, 7 solder balls assigned to a ground voltage, 2 solder balls assigned to an input/output power supply voltage, and 4 solder balls assigned to an input/output ground voltage.

7. The DRAM package of claim 3, wherein the 22 solder balls assigned to the power include 2 solder balls assigned to a high voltage, 7 solder balls assigned to a power supply voltage, 8 solder balls assigned to a ground voltage, 2 solder balls assigned to an input/output power supply voltage, and 3 solder balls assigned to an input/output ground voltage.

8. The DRAM package of claim 2, wherein the plurality of solder balls includes 23 solder balls assigned to a power and exclude a solder ball assigned to a reserved for future use.

9. The DRAM package of claim 8, wherein the 23 solder balls assigned to the power include 2 solder balls assigned to a high voltage, 7 solder balls assigned to a power supply voltage, 8 solder balls assigned to a ground voltage, 2 solder balls assigned to an input/output power supply voltage, and 4 solder balls assigned to an input/output ground voltage.

10. The DRAM package of claim 2, wherein the plurality of solder balls is disposed within a rectangular region of 5.9 mm by 9.1 mm.

11. The DRAM package of claim 2, wherein a pitch among the plurality of solder balls is 0.8 mm.

12. The DRAM package of claim 2, wherein a solder ball of a first row and a first column among the plurality of solder balls is assigned to an input/output power supply voltage.

13. The DRAM package of claim 2, wherein a solder ball of a first row and a seventh column among the plurality of solder balls is assigned to an input/output power supply voltage.

14. The DRAM package of claim 2, wherein a solder ball of a twelfth row and a first column among the plurality of solder balls is assigned to an eight address.

15. The DRAM package of claim 2, wherein a solder ball of an eleventh row and a seventh column among the plurality of solder balls is assigned to a seventh address.

16. The DRAM package of claim 2, wherein among the plurality of solder balls, solder balls of an eighth to eleventh rows and a first column, the eighth to eleventh rows and a second column, the eighth to eleventh rows and a sixth column, and the eighth to eleventh rows and a seventh column are assigned to addresses.

17. A DRAM module comprising:
a plurality of DRAM packages provided on an upper surface of a printed circuit board; and
a connector formed at one side of the printed circuit board and electrically connected with the plurality of DRAM packages,
wherein each of the plurality of DRAM packages is connected with the printed circuit board via a ball grid array, and the ball grid array includes a plurality of solder balls arranged at an equal interval along a row direction and arranged at the equal interval along a column direction.

18. The DRAM module of claim 17, wherein the plurality of solder balls are arranged in an 11-by-7 matrix.

19. The DRAM module of claim 17, further comprising:
a plurality of buffers disposed between the plurality of DRAM packages and the connector.

20. The DRAM module of claim 17, further comprising:
a plurality of lower DRAM package formed at a lower surface of the printed circuit board and electrically connected with the connector,
wherein the plurality of lower DRAM packages has the same structure as the plurality of DRAM packages.

21. The DRAM module of claim 20, wherein the plurality of DRAM packages and the plurality of lower DRAM packages are electrically interconnected through a plurality of via holes penetrating the printed circuit board.

22. The DRAM module of claim 21, further comprising:
a plurality of pads provided at the printed circuit board to be connected with solder balls of the plurality of DRAM packages,
wherein at least one of the plurality of via holes is formed at the same location of the plurality of pads.

23. The DRAM module of claim 21, further comprising:
a plurality of pads provided at the printed circuit board to be connected with solder balls of the plurality of DRAM packages,
wherein at least one of the plurality of via holes is formed between the plurality of pads.

24. The DRAM module of claim 17, further comprising:
a plurality of buffers provided between the DRAM packages and the connector,
wherein the DRAM packages are disposed in two lines along a direction parallel with the one side of the printed circuit board.

25. A graphic module comprising:
a graphic processor unit provided on a printed circuit board; and
at least one DRAM package electrically connected with the graphic processor unit,
wherein the at least one DRAM package is connected with the printed circuit board via a ball grid array, and the ball grid array includes a plurality of solder balls arranged at an equal interval along a row direction and arranged at the equal interval along a column direction.

26. A multimedia device comprising:
a processor;
a DRAM package, an audio unit, a modem unit, a storage unit, a graphic unit, an interface unit, and an image processor unit configured to operate according to a control of the processor;
a speaker configured to communicate with the audio unit;
a user input interface configured to operate according to a control of the interface unit;
a camera configured to operate according to a control of the image processor unit; and
a monitor configured to operate according to a control of the graphic unit,
wherein the DRAM package is connected with a printed circuit board via a ball grid array, and the ball grid array includes a plurality of solder balls arranged at an equal interval along a row direction and arranged at the equal interval along a column direction.

27. The multimedia device of claim 26, wherein a combination of at least two of the processor, the audio unit, the modem unit, the storage unit, the graphic unit, the interface unit, and the image processor unit is formed as a system-on-chip.

28. The multimedia device of claim 26, wherein the printed circuit board, the DRAM package, the processor, the audio unit, the modem unit, the storage unit, the graphic unit, the interface unit, the image processor unit, the speaker, the user input interface, the camera, and the monitor is formed as a mobile device.

29. The multimedia device of claim 26, wherein the graphic unit forms a graphic module with at least one DRAM package and the graphic module communicates with the processor via a connector.

30. The multimedia device of claim 26, wherein the DRAM package forms a DRAM module with another DRAM package and the DRAM module communicates with the processor via a connector.

31. The multimedia device of claim 26, wherein the storage unit constitutes a storage module to communicate with the processor via a connector.

32. The DRAM module of claim 17, further comprising:
a plurality of second DRAM packages provided on a lower surface of the printed circuit board,
wherein the connector is electrically connected with the plurality of DRAM packages and second DRAM packages,
wherein each of the plurality of DRAM packages and second DRAM package is connected with the printed circuit board via a ball grid array,
wherein the ball grid array includes a plurality of solder balls arranged at an equal interval along a row direction and arranged at the equal interval along a column direction, and
wherein the plurality of DRAM packages is electrically connected with the plurality of second DRAM packages through a plurality of via holes, which penetrate the printed circuit board, formed at one or more spaces overlapped with spaces where the solder balls are provided.

33. The DRAM module of claim 17, further comprising:
a plurality of second DRAM packages provided on a lower surface of the printed circuit board,
wherein the connector is electrically connected with the plurality of DRAM packages and second DRAM packages,
wherein each of the plurality of DRAM packages and second DRAM package is connected with the printed circuit board via a ball grid array,
wherein the ball grid array includes a plurality of solder balls arranged at an equal interval along a row direction and arranged at the equal interval along a column direction, and
wherein the plurality of DRAM packages is electrically connected with the plurality of second DRAM packages through a plurality of via holes, which penetrate the printed circuit board, formed at one or more spaces between spaces where the solder balls are provided and is.

34. An electronic apparatus comprising:
a circuit board provided with a function unit configured to perform an operation of the electronic apparatus using data, and formed with pads thereon; and
at least one semiconductor package electrically connected with the function unit to store at least one of the data and the processed data, and formed with a ball grid array to be connected to the respective pads of the circuit board, the ball grid array including a plurality of solder balls arranged at an equal interval along a row direction and arranged at the equal interval along a column direction to correspond to the respective pads.

35. The electronic apparatus of claim 34, further comprising:
a single housing having the circuit board and the semiconductor package.

36. The electronic apparatus of claim 34, further comprising:
a single housing having the circuit board formed with a connector to be connected to the semiconductor package.

37. A semiconductor package comprising:
a semiconductor package body formed with one or more semiconductor chips; and
a ball grid array formed at a lower surface of the semiconductor package body, the ball grid array including a plurality of solder balls disposed in an area of the lower surface of the semiconductor package body and arranged at a same interval along row and column directions thereof.

38. The semiconductor package of claim 37, wherein the one or more semiconductor chips comprises one or more DRAM packages.

39. An electronic apparatus comprising:
a circuit board having a function unit and a pad array having pads; and
a semiconductor package comprising:
a semiconductor package body formed with one or more semiconductor chips; and
a ball grid array formed at a lower surface of the semiconductor package body, the ball grid array including a plurality of solder balls disposed in an area of the lower surface of the semiconductor package body and arranged at a same interval along row and column directions thereof to correspond to the respective pads of the pad array.

40. The electronic apparatus of claim 39, wherein the function unit comprises at least one of a graphic unit, an image processing unit, an interface unit, an audio unit, storage unit, an and user interface unit.

41. The electronic apparatus of claim 39, wherein:
the semiconductor package comprises a first semiconductor package having a first signal and power assignment of the solder balls of the ball grid array and a second semiconductor package having a second signal and power assignment of the solder balls of the ball grid array; and
the pads of the pad array of the circuit board are disposed to correspond to the solder balls of the ball grid array of the first semiconductor package and the second semiconductor package.

42. The electronic apparatus of claim 39, wherein the circuit board comprises one or more via holes formed an area of the pad array between the lower surface and an upper surface to electrically connect conductive materials of the lower surface and the upper surface of the circuit board.

43. The electronic apparatus of claim 41, wherein the first signal and power assignment of the first semiconductor package and the second signal and power assignment of the second semiconductor package comprises a common signal and power assignment.
